(19) United States
(12) Patent Application Publication
(10) Pub. No.: US 2026/0052859 A1
(43) Pub. Date: Feb. 19, 2026

(54) DISPLAY MODULE AND ELECTRONIC DEVICE INCLUDING THE SAME

(71) Applicant: Samsung Display Co., Ltd., Yongin-si (KR)

(72) Inventors: HEEJU WOO, Yongin-si (KR); KIYONG KIM, Yongin-si (KR); CHOLONG WON, Yongin-si (KR); HYUNGBIN CHO, Yongin-si (KR)

(73) Assignee: Samsung Display Co., Ltd., Yongin-si (KR)

(21) Appl. No.: 19/297,158

(22) Filed: Aug. 12, 2025

(30) Foreign Application Priority Data
Aug. 13, 2024 (KR) 10-2024-0108264

(51) Int. Cl. H10K 59/131

(52) U.S. Cl. CPC H10K 59/131

(57) ABSTRACT

A display module may include a display panel that may include a display region, and a non-display region disposed adjacent to the display region, wherein a pad region is disposed in the non-display region, the display panel may include pixels disposed in the display region, and a signal pad connected to the pixels through a signal line and is disposed in the pad region, the signal pad may include a first conductive pattern connected to a portion of the signal line, a second conductive pattern disposed on the first conductive pattern, a third conductive pattern disposed on the second conductive pattern, and an insulating pattern disposed between the second conductive pattern and the third conductive pattern, an opening may be disposed in at least one of the first conductive pattern and the second conductive pattern, and the opening may overlap the insulating pattern.

### CROSS-REFERENCE TO RELATED APPLICATION(S)

This application claims priority under 35 U.S.C. § 119 to and the benefits of Korean Patent Application No. 10-2024-0108264 filed Aug. 13, 2024, in the Korean Intellectual Property Office, the entire contents of which are incorporated herein by reference.

### BACKGROUND

### 1. Technical Field

The disclosure herein relates to a display module and an electronic device that include a pad region.

### 2. Description of the Related Art

Multimedia electronic devices such as televisions, mobile phones, tablet computers, navigation systems, and game consoles may include a display module configured to display images and sense external inputs.

The display module may be bonded and electrically connected to a driver chip that provides electrical signals required for displaying images.

### SUMMARY

The disclosure provides a display module and an electronic device that exhibit excellent bonding reliability.

An embodiment of the disclosure provides a display module including a display panel including a display region, and a non-display region disposed adjacent to the display region, wherein a pad region is disposed in the non-display region, the display panel may include pixels disposed in the display region, and a signal pad connected to the pixels through a signal line and is disposed in the pad region, the signal pad may include a first conductive pattern connected to a portion of the signal line, a second conductive pattern disposed on the first conductive pattern, a third conductive pattern disposed on the second conductive pattern, and an insulating pattern disposed between the second conductive pattern and the third conductive pattern, an opening may be disposed in at least one of the first conductive pattern and the second conductive pattern, the opening may overlap the insulating pattern.

In an embodiment, the insulating pattern may include a central portion overlapping the opening, the insulating pattern may further include a side portion that may not overlap the opening, and the central portion may protrude further from the at least one of the first conductive pattern and the second conductive pattern towards the third conductive pattern than the side portion.

In an embodiment, the side portion of the insulating pattern may overlap each of the first conductive pattern and the second conductive pattern.

In an embodiment, the insulating pattern may have a greater area than the opening in a plan view.

In an embodiment, the opening is disposed in the second conductive pattern, the insulating pattern may fill the opening, and the insulating pattern may be disposed directly on the first conductive pattern.

In an embodiment, the opening may include a first opening and a second opening, the first opening may be disposed in the first conductive pattern, the first opening may overlap the insulating pattern, and the second opening may be disposed in the second conductive pattern.

In an embodiment, the signal pad further may include a reinforcing pattern having a greater hardness than the insulating pattern, and the reinforcing pattern may overlap the opening in a plan view.

In an embodiment, the reinforcing pattern may include metal.

In an embodiment, the reinforcing pattern may include molybdenum (Mo).

In an embodiment, the opening is disposed in the second conductive pattern, the reinforcing pattern may be disposed directly under the first conductive pattern, and the insulating pattern may be disposed directly on the first conductive pattern.

In an embodiment, the second conductive pattern may have the opening defined therein, the reinforcing pattern may be disposed in the opening defined in the second conductive pattern, and the insulating pattern may be disposed directly on the reinforcing pattern.

In an embodiment, the opening may include a first opening and a second opening, the first opening may be disposed in the first conductive pattern, the second opening may be disposed in the second conductive pattern, the insulating pattern may overlap the first opening and the second opening, the reinforcing pattern may be disposed in the first opening, and the insulating pattern may be disposed directly on the reinforcing pattern.

In an embodiment, the opening may be disposed in the first conductive pattern, the reinforcing pattern may be disposed in the opening, and the insulating pattern may be disposed directly on the second conductive pattern.

In an embodiment, the display panel may include a base layer, a circuit element layer disposed on the base layer, and a light emitting element layer disposed on the circuit element layer in the display region, the light emitting element layer may include a light emitting element, the circuit element layer may include a transistor that includes a semiconductor pattern that includes a channel, a source, and a drain, and a gate electrode, the semiconductor pattern and the gate electrode may be disposed at a different layer from each other, a first connection electrode connected to the transistor, and a second connection electrode connected to the light emitting element, the first conductive pattern may be formed from a same layer as the first connection electrode, and the second conductive pattern may be formed from a same layer as the second connection electrode.

In an embodiment, the circuit element layer may further include an upper electrode that overlaps the gate electrode in a plan view, a capacitor that includes the upper electrode and the gate electrode, the signal pad may further include a reinforcing pattern having a greater hardness than the insulating pattern, the reinforcing pattern may may overlap the opening in a plan view, and the reinforcing pattern and the upper electrode may be formed from a same layer.

In an embodiment, the display module may further include an input sensing unit disposed on the display panel, wherein the input sensing unit may include a first sensing conductive layer, a first sensing insulating layer disposed on the first sensing conductive layer, and a second sensing conductive layer disposed on the first sensing insulating layer, and the third conductive pattern of the signal pad and at least one of the first sensing conductive layer and the second sensing conductive layer of the input sensing unit may be formed from a same layer.

In an embodiment, the insulating pattern may include a polymer.

In an embodiment, the first conductive pattern, the second conductive pattern, and the third conductive pattern may each include a first layer, a second layer, and a third layer, and the first layer and the third layer may have a smaller electrical conductivity than the second layer.

In an embodiment, the first layer and the third layer may each include titanium (Ti), and the second layer may include aluminum (Al).

In an embodiment of the inventive concept, an electronic device may include a display module that may include a display panel including a display region, and a non-display region disposed adjacent to the display region, wherein a pad region is disposed in the non-display region, the display panel may include pixels disposed in the display region, and a signal pad connected to the pixels through a signal line and is disposed in the pad region, and an input sensing unit may be disposed on the display panel, an electronic device may include an electronic component including a bump electrode disposed in the pad region, and an adhesive layer bonding the display panel and the electronic component, wherein the input sensing unit may include a first sensing conductive layer disposed on the display panel, a first sensing insulating layer disposed on the first sensing conductive layer, and a second sensing conductive layer disposed on the first sensing insulating layer, the signal pad may include a first conductive pattern connected to a portion of the signal line, a second conductive pattern disposed on the first conductive pattern, a third conductive pattern disposed on the second conductive pattern, and an insulating pattern disposed between the second conductive pattern and the third conductive pattern, wherein an opening may be disposed in at least one of the first conductive pattern and the second conductive pattern, the opening may overlap the insulating pattern, the insulating pattern may include a central portion overlapping the opening and a side portion that may not overlap the opening, and the central portion may protrude further from at least one of the first conductive pattern and the second conductive pattern towards the third conductive pattern than the side portion.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a combined schematic perspective view of an electronic device according to an embodiment of the disclosure;

FIG. 2 is an exploded schematic perspective view of an electronic device according to an embodiment of the disclosure;

FIG. 3 is a schematic cross-sectional view of a display module according to an embodiment of the disclosure;

FIG. 4 is a schematic plan view of a display panel according to an embodiment of the disclosure;

FIG. 5 is a schematic plan view of an input sensing unit according to an embodiment of the disclosure;

FIG. 6 is a schematic cross-sectional view of a display module according to an embodiment of the disclosure;

FIG. 7 is a schematic perspective view of an electronic device according to an embodiment of the disclosure;

FIG. 8A is a schematic plan view of a pad region according to an embodiment of the disclosure;

FIG. 8B is a schematic cross-sectional view of a pad region according to an embodiment of the disclosure;

FIGS. 9A to 9E are each schematic cross-sectional views of a pad region according to an embodiment of the disclosure; and

FIGS. 10A and 10B are each schematic cross-sectional views of a pad region according to an embodiment of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc., (hereinafter individually or collectively referred to as “elements”), of the various embodiments may be otherwise combined, separated, interchanged, and/or redisposed without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc., may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the disclosure. Further, the blocks, parts, and/or modules of some embodiments may be physically combined into more complex blocks, parts, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

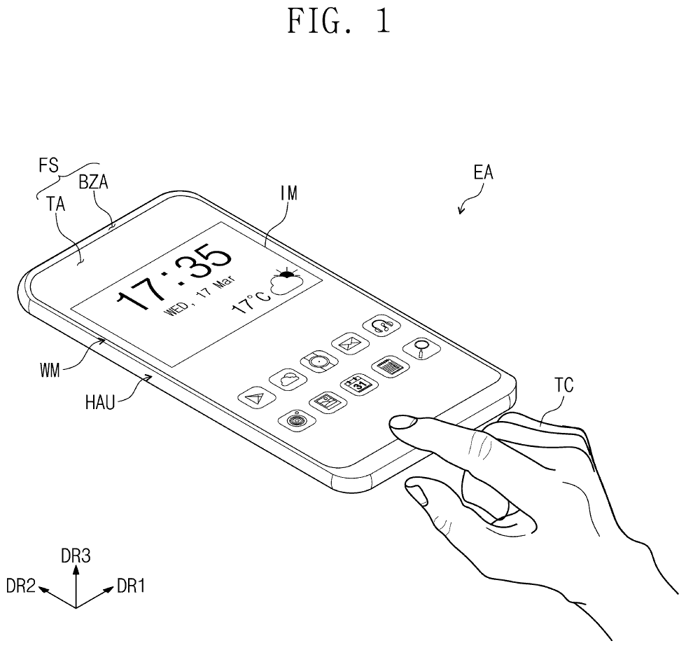

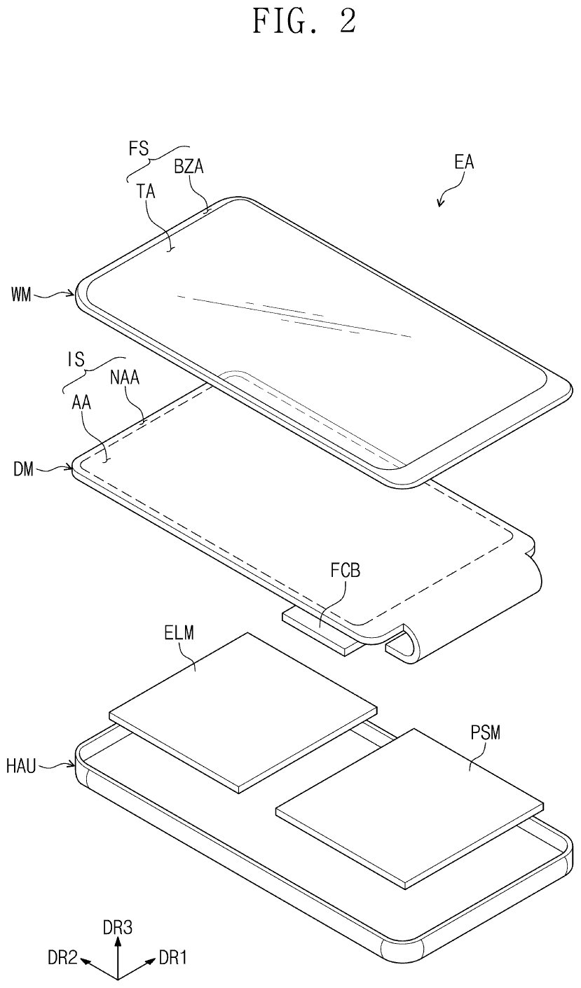

FIG. 1 is a combined schematic perspective view of an electronic device EA according to an embodiment of the disclosure. FIG. 2 is an exploded schematic perspective view of an electronic device EA according to an embodiment of the disclosure.

Referring to FIGS. 1 and 2, the electronic device EA may be a device that is activated in response to electrical signals, displays an image IM, and senses an external input TC. For example, the electronic device EA may include devices such as monitors, mobile phones, tablet computers, navigation systems, and game consoles. However, embodiments of the electronic device EA are presented as examples, and thus are not limited to any one without departing from the disclosure. In the embodiment, as an example, a mobile phone is shown as the electronic device EA.

The electronic device EA may have a rectangular shape having short sides extending in a first direction DR1 and long sides extending in a second direction DR2 crossing the first direction DR1 in a plan view. However, the embodiment of the disclosure is not limited thereto, and the electronic device EA may have various shapes such as a circular shape and a polygonal shape.

In the embodiment, a third direction DR3 may be a direction perpendicular to a plane defined by the first direction DR1 and the second direction DR2. A front surface (or upper surface) and a rear surface (or lower surface) of each member constituting the electronic device EA may oppose each other in the third direction DR3 and a normal direction of each of the front and rear surfaces may substantially be parallel to the third direction DR3. A distance between the front surface and the rear surface defined in the third direction DR3 may correspond to a thickness of a member.

Herein, “on a plane” may be defined as a state viewed in the third direction DR3 (or “in a plan view”). Herein, “on a cross-section” may be defined as a state viewed in the first direction DR1 or the second direction DR2. Directions indicated by the first to third directions DR1, DR2, and DR3 are relative concepts, and may thus be changed to other directions.

The electronic device EA may be rigid or flexible. The term “flexible” indicates a property of being bendable, and may include all from a structure being completely foldable to a structure being bendable up to several nanometers. For example, the flexible electronic device EA may include a curved electronic device, a rollable electronic device, or a foldable electronic device.

The electronic device EA may display the image IM through a display surface FS parallel to each of the first direction DR1 and the second direction DR2. The image IM may include still images as well as dynamic images. FIG. 1 shows a clock and icons as an example of the image IM.

For example, the display surface FS of the electronic device EA may include a plane alone or may further include a curved surface bent from at least a side of the plane. The display surface FS may correspond to a front surface of the electronic device EA and may also correspond to a front surface of a window WM. Hereinafter, like reference numerals will be given for the display surface FS of the electronic device EA and the front surface of the window WM.

The electronic device EA according to an embodiment may sense an external input TC applied from the outside. The external input TC may include various forms of inputs such as force, pressure, temperature, or light. In the embodiment, a user's hand applied to the front surface is shown as the external input TC. However, this is presented as an example, and the external input TC may include inputs applied in case of being close to the electronic device EA, such as contact by a pen or hovering.

The electronic device EA may sense user input through the display surface FS defined in the front surface and respond to sensed input signals. However, a region of the electronic device EA for sensing the external input TC is not limited to the front surface of the electronic device EA, and may vary depending on the design of the electronic device EA. For example, the electronic device EA may sense user's input applied to a side surface or a rear surface.

The electronic device EA may include a window WM, a display module DM, an electronic module ELM, a power module PSM, and a housing HAU. The window WM and the housing HAU may be bonded to form an outer portion of the electronic device EA.

The window WM may be disposed on the display module DM. The window WM may cover (or overlap) a front surface IS of the display module DM and may protect the display module DM from external shocks and scratches. The window WM may be bonded to the display module DM through an adhesive layer.

The window WM may include an optically transparent insulating material. For example, the window WM may include glass or a synthetic resin as a base film. The window WM may have a single-layer structure or a multi-layer structure. For example, the window WM having a multi-layer structure may include synthetic resins bonded through an adhesive, or a glass film and a synthetic resin film bonded through an adhesive. The window WM may further include functional layers such as an anti-fingerprint layer, a phase control layer, or a hard coating layer disposed on an optically transparent base film.

The front surface of the window WM may correspond to the front surface FS of the electronic device EA. The front surface of the window WM may include a transmission region TA and a bezel region BZA.

The transmission region TA may be an optically transparent region. The transmission region TA may transmit the image IM provided from the display module DM. In the embodiment, the transmission region TA is shown to have a rectangular shape but is not limited thereto, and the transmission region TA may have various shapes.

The bezel region BZA may be a region having a lower light transmittance than the transmission region TA. The bezel region BZA may correspond to a region in which a material having a color is printed. The bezel region BZA may prevent the transmission of light, thereby preventing a component of the display module DM disposed to overlap the bezel region BZA from being viewed from the outside.

The bezel region BZA may be positioned adjacent to the transmission region TA. The shape of the transmission region TA may be substantially defined by the bezel region BZA. For example, the bezel region BZA may be disposed outside the transmission region TA to surround the transmission region TA. However, this is presented as an example, and the bezel region BZA may be positioned adjacent to only one side of the transmission region TA or may be disposed not on the front surface FS but on the side surface of the electronic device EA. The bezel region BZA may not be provided.

The display module DM may be disposed between the window WM and the housing HAU. The display module DM may display the image IM and sense the external input TC. The image IM may be displayed on the front surface IS of the display module DM. The front surface IS of the display module DM may include an active region AA and a peripheral region NAA.

The active region AA may be a region activated in response to electrical signals. For example, the active region AA may be a region in which the image IM is displayed and also the external input TC is sensed. The active region AA may overlap at least a portion of the transmission region TA. Accordingly, users may view the image IM through the transmission region TA or provide the external input TC. However, this is presented as an example, and in the active region AA, a region in which the image IM is displayed and a region in which the external input TC is sensed may be separated and are not limited to an embodiment.

The peripheral region NAA may be positioned adjacent to the active region AA. For example, the peripheral region NAA may surround the active region AA. A driving circuit, a driving line, or the like for driving the active region AA may be disposed in the peripheral region NAA. The peripheral region NAA may overlap at least a portion of the bezel region BZA, and components disposed in the peripheral region NAA may be prevented from being viewed from the outside by the bezel region BZA.

The display module DM may include a display panel and an input sensing unit. The display panel may display the image IM, and the input sensing unit may sense the external input TC. A detailed description thereof will be given later.

A portion of the display module DM may be bent around a bending axis extending in the first direction DR1. For example, the portion of the display module DM may be bent toward a rear surface of the display module DM corresponding to the active region AA. A flexible circuit board FCB may be connected to the bent portion of the display module DM, and thus, the flexible circuit board FCB may overlap the display module DM in a plan view.

The flexible circuit board FCB may be electrically connected to the display module DM on a side (e.g., single side) of the display module DM. The flexible circuit board FCB may generate electrical signals provided to the display module DM or receive signals generated from the display module DM and calculate result values including information on position or intensity where the external input TC is sensed.

The electronic module ELM and the power module PSM may be disposed below the display module DM. The electronic module ELM and the power module PSM may be electrically connected through a separate circuit board.

The power module PSM may supply power required for the operation of the electronic device EA. For example, the power module PSM may include a typical battery module.

The electronic module ELM may include various functional modules that enable the operation of the electronic device EA. For example, the electronic module ELM may include a control module, a wireless communication module, an image input module, an audio input module, an audio output module, a memory, an optical module, and an external interface module. The electronic module ELM may include a main circuit board, and the modules of the electronic module ELM may be mounted on the main circuit board or electrically connected to the main circuit board through a separate circuit board.

Of the electronic module ELM, the control module may control the overall operation of the electronic device EA. For example, the control module may activate or deactivate the display module DM in accordance with user inputs. The control module may include at least one microprocessor. Of the electronic module ELM, the optical module may include a camera module, a proximity sensor, a biometric sensor for recognizing a part of a user's body (e.g., fingerprint, iris, or face), or a light-emitting lamp.

The housing HAU, combined with the window WM, may provide an internal space that accommodates the display module DM, the electronic module ELM, the power module PSM, and the flexible circuit board FCB. The housing HAU may include a material having a greater rigidity. For example, the housing HAU may include multiple frames and/or plates including glass, plastic, or metal, or formed of a combination thereof. The housing HAU may absorb shocks applied from the outside or prevent foreign material/moisture from penetrating from the outside to protect components of the electronic device EA accommodated in the housing HAU.

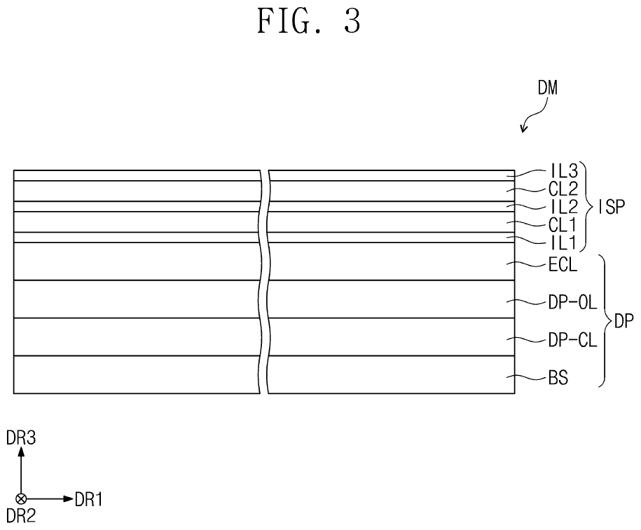

FIG. 3 is a schematic cross-sectional view of a display module DM according to an embodiment of the disclosure.

Referring to FIG. 3, the display module DM may include a display panel DP and an input sensing unit ISP. The input sensing unit ISP may be disposed on the display panel DP. For example, the input sensing unit ISP may be disposed (e.g., disposed directly) on the display panel DP. In the embodiment, the phrase “the input sensing unit ISP is disposed (e.g., disposed directly) on the display panel DP” indicates that the input sensing unit ISP is formed on the display panel DP through a continuous process, and thus the input sensing unit ISP and the display panel DP are combined without a separate adhesive layer. For example, the components of the input sensing unit ISP may be formed on a base surface provided by the display panel DP.

The display panel DP may display images in response to electrical signals. The display panel DP according to an embodiment may be a light emitting display panel, and is not particularly limited thereto. For example, the display panel DP may be an organic light emitting display panel, an inorganic light emitting display panel, or a quantum dot light emitting display panel. An emission layer of the organic light emitting display panel may include an organic light emitting material, and an emission layer of the inorganic light emitting display panel may include an inorganic light emitting material. An emission layer of the quantum dot light emitting display panel may include quantum dots, quantum rods, and the like. Hereinafter, the display panel DP is described as an organic light emitting display panel.

The display panel DP may include a base substrate BS, a circuit element layer DP-CL, a light emitting element layer DP-OL, and an encapsulation layer ECL, which are sequentially stacked on each other in the third direction DR3.

The base substrate BS may be a rigid substrate, or a flexible substrate that is bendable, foldable, rollable, or the like. For example, the base substrate BS may be a glass substrate, a metal substrate, or a polymer substrate. The base substrate BS may provide a base surface on which the circuit element layer DP-CL is disposed.

The base substrate BS may include an inorganic layer, an organic layer, or a composite material layer. The base substrate BS may have a single-layer structure or a multi-layer structure. For example, the base substrate BS having a multi-layer structure may include synthetic resin layers and multi-layer or single-layer inorganic layers disposed between the synthetic resin layers. The synthetic resin layer may include an acryl-based resin, a methacrylate-based resin, polyisoprene, a vinyl-based resin, an epoxy-based resin, a urethane-based resin, a cellulose-based resin, a siloxane-based resin, a polyamide-based resin, or a perylene-based resin, but materials of the synthetic resin layer are not limited thereto.

The circuit element layer DP-CL may be disposed on the base substrate BS. The circuit element layer DP-CL may include at least one insulating layers, semiconductor patterns, and conductive patterns. The insulating layer, semiconductor pattern, and conductive pattern included in the circuit element layer DP-CL may form driving elements such as transistors, signal lines, and pads.

The light emitting element layer DP-OL may be disposed on the circuit element layer DP-CL. The light emitting element layer DP-OL may include light emitting elements, each emitting light. For example, the light emitting elements may be an organic light emitting element, an inorganic light emitting element, a micro LED, or a nano LED. The light emitting elements of the light emitting element layer DP-OL may be electrically connected to driving elements of the circuit element layer DP-CL, and may thus emit light in response to electrical signals provided by the driving elements.

The encapsulation layer ECL may be disposed on the light emitting element layer DP-OL to seal the light emitting elements. The encapsulation layer ECL may include at least one thin film for improving optical efficiency of the light emitting element layer DP-OL or protecting the light emitting element layer DP-OL. For example, the encapsulation layer ECL may include at least one of an inorganic film and an organic film. The inorganic film of the encapsulation layer ECL may protect the light emitting elements from moisture/oxygen. The organic film of the encapsulation layer ECL may protect the light emitting elements from foreign material such as dust particles.

The input sensing unit ISP may sense external inputs and provide input signals including information on the external inputs, and thus the display panel DP may display images corresponding to the external inputs. The input sensing unit ISP may be driven in various ways such as a capacitive method, a resistive method, an infrared method, a sound wave method, or a pressure method, and the driving method of the input sensing unit ISP is not limited to any one as long as it is capable of sensing external inputs. In the embodiment, the input sensing unit ISP is described as an input sensing panel driven in a capacitive method.

The input sensing unit ISP may include a base layer IL1, a first sensing conductive layer CL1, a first sensing insulating layer IL2, a second sensing conductive layer CL2, and a second sensing insulating layer IL3, which are sequentially stacked on each other in the third direction DR3. The base layer IL1 of the input sensing unit ISP may be in contact with the encapsulation layer ECL. However, the embodiment of the disclosure is not limited thereto, and at least one of the base layer IL1 or the second sensing insulating layer IL3 may not be provided.

The first sensing conductive layer CL1 and the second sensing conductive layer CL2 may each have a single-layer structure or a multi-layer structure. The conductive layer having a multi-layer structure may include two or more layers of transparent conductive layers and metal layers. The conductive layer having a multi-layer structure may include metal layers having different metals. The transparent conductive layer may include at least one of indium tin oxide (ITO), indium zinc oxide (IZO), zinc oxide (ZnO), indium tin zinc oxide (ITZO), PEDOT, a metal nano wire, or graphene. The metal layer may include at least one of molybdenum, silver, titanium, copper, aluminum, or an alloy thereof. For example, the first sensing conductive layer CL1 and the second sensing conductive layer CL2 may each have a two-layer structure, for example, a two-layer structure of ITO/copper, or a three-layer structure of titanium/aluminum/titanium, without limitation.

The first sensing conductive layer CL1 and the second sensing conductive layer CL2 may each include sensing conductive patterns. The sensing conductive patterns of the first sensing conductive layer CL1 and the second sensing conductive layer CL2 may form sensing electrodes constituting the input sensing unit ISP and sensing lines connected thereto.

The base layer IL1, the first sensing insulating layer IL2, and the second sensing insulating layer IL3 may each include at least one of an inorganic film or an organic film. For example, the inorganic film may include at least one of aluminum oxide, titanium oxide, silicon oxide, silicon oxynitride, zirconium oxide, or hafnium oxide, and the organic film may include at least one of an acryl-based resin, a methacrylic-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin. However, materials of the inorganic film and the organic film are not limited to the above examples. In an embodiment, the base layer IL1 may include an inorganic film, and the first sensing insulating layer IL2 and the second sensing insulating layer IL3 may include organic films, but the embodiment of the disclosure is not limited thereto.

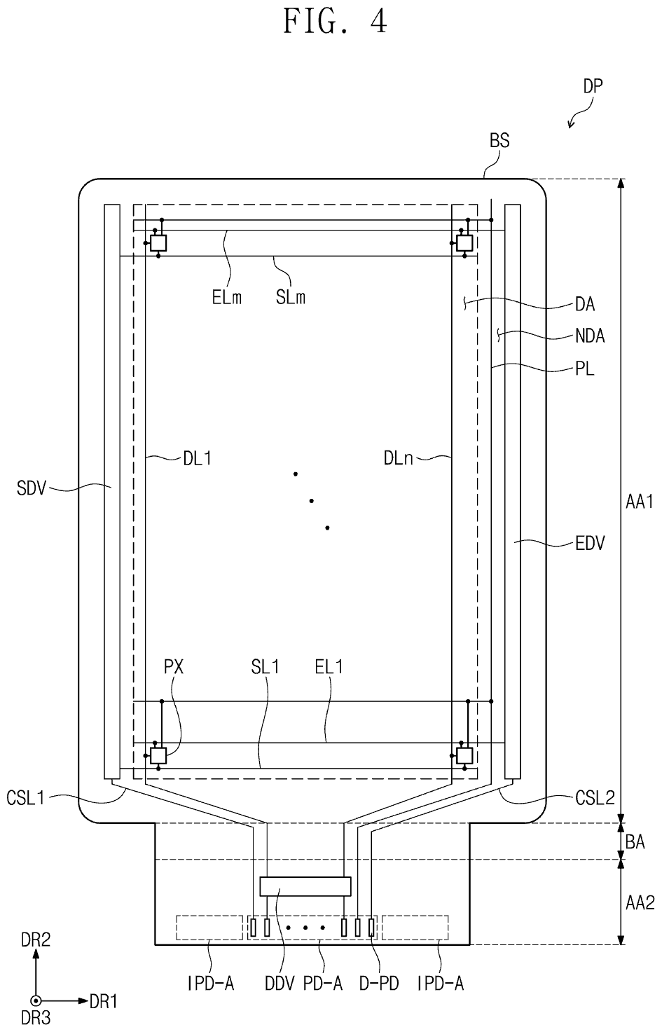

FIG. 4 is a schematic plan view of a display panel DP according to an embodiment of the disclosure.

Referring to FIG. 4, the display panel DP may include a base substrate BS, pixels PX, signal lines SL1 to SLm, DL1 to DLn, EL1 to ELm, CSL1, CSL2, and PL electrically connected to the pixels PX, a scan driver SDV, an emission driver EDV, a data driver DDV, and display pads D-PD.

The base substrate BS may provide a base surface on which electrical elements and lines of the display panel DP are disposed. The base substrate BS may include a first base region AA1, a bending region BA, and a second base region AA2, which are separated in the second direction DR2. The bending region BA may extend from the first base region AA1 in the second direction DR2. The second base region AA2 may extend from the bending region BA in the second direction DR2. Accordingly, the first base region AA1 and the second base region AA2 may be spaced apart from each other with the bending region BA between the first base region AA1 and the second base region AA2.

The first base region AA1 may include a display region DA. The display region DA may be a region in which light emitting elements of the pixels PX are disposed. Accordingly, the display region DA may display images through the pixels PX. The display region DA may correspond to the active region AA (see FIG. 2) of the display module DM (see FIG. 2) and may overlap the transmission region TA (see FIG. 2) of the window WM (see FIG. 2).

The first base region AA1, the bending region BA, and the second base region AA2 excluding the display region DA may be defined as a non-display region NDA. The non-display region NDA may be a region adjacent to the display region DA and displaying no image. The non-display region NDA may surround the display region DA. In the non-display region NDA, the display pads D-PD electrically connected to the scan driver SDV, the emission driver EDV, the data driver DDV for driving the pixels PX, and signal lines SL1 to SLm, DL1 to DLn, EL1 to ELm, CSL1, CSL2, and PL may be disposed. The signal lines SL1 to SLm, DL1 to DLn, EL1 to ELm, CSL1, CSL2, and PL electrically connected to the pixels PX may be disposed to extend in the non-display region NDA.

The bending region BA may be a region bent with respect to a bending axis extending in the first direction DR1. For example, the bending region BA may be bent toward a rear surface of the display panel DP corresponding to the first base region AA1. The second base region AA2 extending from a side (e.g., single side) of the bending region BA may overlap the first base region AA1 in a plan view as a result of the bending of the bending region BA. For example, the second base region AA2 may be disposed on the rear surface of the display panel DP corresponding to the first base region AA1.

The bending region BA and the second base region AA2 may each have a smaller width than the first base region AA1 in the first direction DR1. The bending region BA has a smaller width than the first base region AA1 in the direction parallel to the bending axis, and thus the bending region BA may be readily bent. However, this is shown as an example, and at least one of the widths of the bending region BA and the second base region AA2 in the first direction DR1 may be the same as the width of the first base region AA1, and the embodiment of the disclosure is not limited to any one.

The second base region AA2 may be a region that is provided as a substantially flat area located below the first base region AA1 as a result of the bending of the bending region BA. The second base region AA2 may be a region where, among the signal lines SL1 to SLm, DL1 to DLn, EL1 to ELm, CSL1, CSL2, and PL, signal lines extending toward the display pads D-PD via the bending region BA and the data driver DDV are disposed.

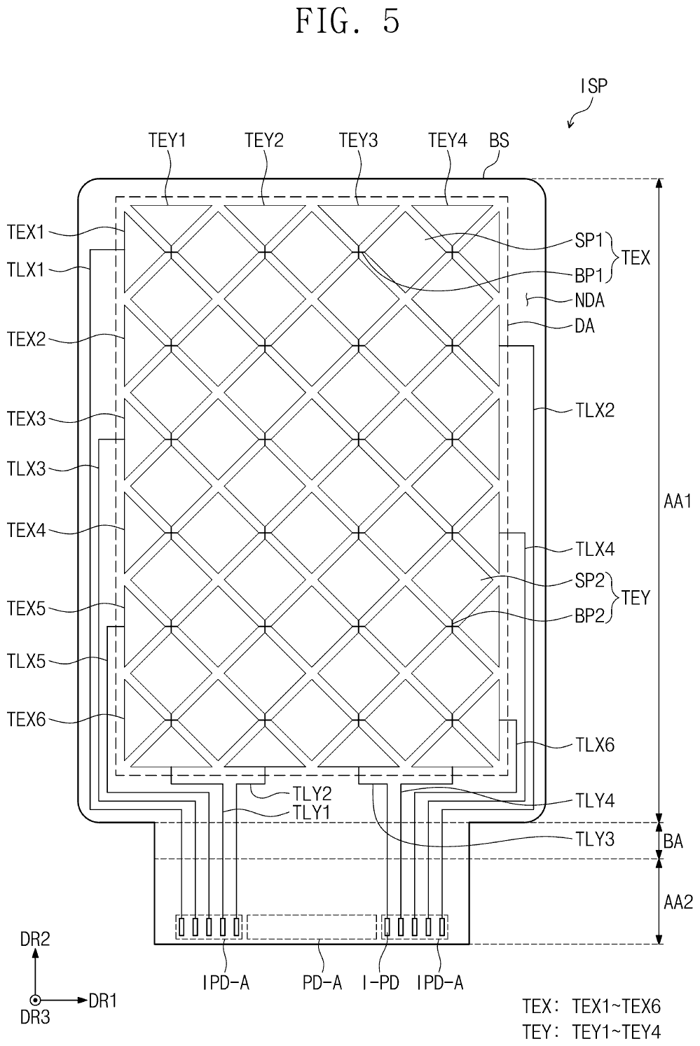

The region where the display pads D-PD are disposed and the region where sensing pads I-PD (see FIG. 5), which will be described later, are disposed, may be divided into a display pad region PD-A and a sensing pad region IPD-A, respectively. FIG. 4 shows, by way of example, that the display pad region PD-A and the sensing pad region IPD-A are divided in the first direction DR1. For example, the sensing pad region IPD-A may be provided adjacent to both sides of the second base region AA2 in the first direction DR1, and the display pad region PD-A may be provided in the center. However, the embodiment of the disclosure is not necessarily limited thereto, and the positions where the display pads D-PD and the sensing pads I-PD (see FIG. 5) are disposed may be variously changed.

The flexible circuit board FCB (see FIG. 2) may be disposed in the second base region AA2 in which the display pads D-PD and the sensing pads I-PD (see FIG. 5) are disposed, and may be electrically connected to the display pads D-PD and the sensing pads I-PD (see FIG. 5). The flexible circuit board FCB (see FIG. 2) disposed adjacent a lower end of the second base region AA2 may be positioned on the rear surface of the display panel DP as a result of the bending of the bending region BA. As the second base region AA2 and the flexible circuit board FCB (see FIG. 2) are positioned below the first base region AA1 on the front surface of the electronic device EA (see FIG. 2), a bezel area of the electronic device EA (see FIG. 2) may be reduced.

The pixels PX may each include a pixel driving circuit including transistors (e.g., switching transistor, driving transistor, and the like) and at least one capacitor, and a light emitting element electrically connected to the pixel driving circuit. The pixels PX may generate light in response to electrical signals applied to each of the pixels PX and display images through the display region DA. According to an embodiment, some of the pixels PX may include a transistor disposed in the non-display region NDA, but the embodiment of the disclosure is not limited to any one.

The scan driver SDV and the emission driver EDV may be disposed in the non-display region NDA corresponding to the first base region AA1. The data driver DDV may be disposed in the non-display region NDA corresponding to the second base region AA2. In an embodiment, the data driver DDV may be provided in the form of an integrated circuit chip mounted in the non-display region NDA of the display panel DP. However, the data driver DDV is not limited thereto, and may also be mounted on the flexible circuit board FCB (see FIG. 2).

The signal lines SL1 to SLm, DL1 to DLn, EL1 to ELm, CSL1, CSL2, and PL may include scan lines SL1 to SLm, data lines DL1 to DLn, light emitting lines EL1 to ELm, first and second control lines CSL1 and CSL2, and a power line PL, where m and n indicate natural numbers greater than 1.

The data lines DL1 to DLn may be insulated from and cross the scan lines SL1 to SLm and the light emitting lines EL1 to ELm. For example, the scan lines SL1 to SLm may extend in the first direction DR1 and be electrically connected to the scan driver SDV. The data lines DL1 to DLn may extend in the second direction DR2 and be electrically connected to the data driver DDV. The light emitting lines EL1 to ELm may extend in the first direction DR1 and be electrically connected to the emission driver EDV.

The power line PL may include a portion extending in the first direction DR1 and a portion extending in the second direction DR2. Of the power line PL, the portion extending in the first direction DR1 and the portion extending in the second direction DR2 may be disposed at different layers or may be integral with each other at a same layer. The portion of the power line PL, which extends in the first direction DR1 may be electrically connected to the pixels PX and the portion of the power line PL, which extends in the second direction DR2. The portion of the power line PL, which extends in the second direction DR2, may be disposed in the non-display region NDA and may be electrically connected to the display pads D-PD via the bending region BA and the second base region AA2 from the first base region AA1. The power line PL may provide a first voltage to the pixels PX.

A first control line CSL1 may be electrically connected to the scan driver SDV, and may extend toward a lower end of the second base region AA2 via the bending region BA. A second control line CSL2 may be electrically connected to the emission driver EDV, and may extend toward a lower end of the second base region AA2 via the bending region BA.

The display pads D-PD may be disposed adjacent to the lower end of the second base region AA2. In the second base region AA2, the display pads D-PD may be disposed closer to the lower end of the base substrate BS than the data driver DDV. The display pads D-PD may be spaced apart in the first direction DR1. The power line PL, the first control line CSL1, and the second control line CSL2 may each be electrically connected to corresponding display pads D-PD among the display pads D-PD. The data lines DL1 to DLn may each be electrically connected to corresponding display pads D-PD among the display pads D-PD via the data driver DDV.

The display pads D-PD may be electrically connected to the flexible circuit board FCB (see FIG. 2) via an adhesive layer, and electrical signals provided from the flexible circuit board FCB (see FIG. 2) may be transmitted to the display panel DP via the display pads D-PD. However, the way the display pads D-PD and the flexible circuit board FCB (see FIG. 2) are connected is not limited thereto.

The scan driver SDV may generate scan signals in response to scan control signals. The scan signals may be applied to the pixels PX via the scan lines SL1 to SLm. The data driver DDV may generate data voltages corresponding to image signals in response to data control signals. The data voltages may be applied to the pixels PX via the data lines DL1 to DLn. The emission driver EDV may generate emission signals in response to emission control signals. The emission signals may be applied to the pixels PX via the light emitting lines EL1 to ELm.

The pixels PX may be provided with the data voltages in response to scan signals. The pixels PX may generate images by emitting light of luminance corresponding to data voltages in response to emission signals. The emission duration of the pixels PX may be controlled by the emission signals.

FIG. 5 is a schematic plan view of an input sensing unit ISP according to an embodiment of the disclosure. FIG. 5 briefly shows components of the input sensing unit ISP disposed on the base substrate BS described above for convenience of description.

In an embodiment, the input sensing unit ISP may be driven by a mutual-cap type. Referring to FIG. 5, the input sensing unit ISP may include first sensing electrodes TEX: TEX1 to TEX6, second sensing electrodes TEY: TEY1 to TEY4, first sensing lines TLX1 to TLX6, second sensing lines TLY1 to TLY4, and sensing pads I-PD. However, the embodiment of the disclosure is not limited thereto, and the input sensing unit ISP may be driven by a self-cap type.

The first sensing electrodes TEX may each extend in the first direction DR1, and the first sensing electrodes TEX may be arranged (or disposed) in the second direction DR2. FIG. 5 shows six first sensing electrodes TEX1 to TEX6 as an example. However, the number of first sensing electrodes TEX included in the input sensing unit ISP is not limited thereto. A first sensing electrode TEX (e.g., single first sensing electrode TEX) may include first sensing patterns SP1 disposed in the first direction DR1 and first connection patterns BP1 connecting the first sensing patterns SP1.

The second sensing electrodes TEY may each extend in the second direction DR2, and the second sensing electrodes TEY may be arranged (or disposed) in the first direction DR1. FIG. 5 shows four second sensing electrodes TEY1 to TEY4 as an example. However, the number of second sensing electrodes TEY included in the input sensing unit ISP is not limited thereto. A second sensing electrode TEY (e.g., single second sensing electrode TEY) may include second sensing patterns SP2 disposed in the second direction DR2 and second connection patterns BP2 connecting the second sensing patterns SP2.

The first sensing electrodes TEX and the second sensing electrodes TEY may be electrically insulated. The input sensing unit ISP may sense external inputs through changes in capacitance between the first sensing electrodes TEX and the second sensing electrodes TEY. The first sensing electrodes TEX and the second sensing electrodes TEY may be disposed in a region corresponding to the display region DA of the base substrate BS. Accordingly, the electronic device EA (see FIG. 1) may display images through the display region DA and also sense external inputs applied to the display region DA.

The first sensing lines TLX1 to TLX6 may be disposed in the non-display region NDA and be electrically connected to the first sensing electrodes TEX1 to TEX6, respectively. Some of the first sensing lines TLX1 to TLX6 may be disposed on a left side of the non-display region NDA, and a remaining may be disposed on a right side of the non-display region NDA. For example, the first sensing lines TLX1, TLX3, and TLX5 connected to the first sensing electrodes TEX1, TEX3, and TEX5 disposed in odd rows may be respectively connected to the left sides of the first sensing electrodes TEX1, TEX3, and TEX5, and the first sensing lines TLX2, TLX4, and TLX6 connected to the first sensing electrodes TEX2, TEX4, and TEX6 disposed in even rows may be respectively connected to the right sides of the first sensing electrodes TEX2, TEX4, and TEX6. However, the arrangement of the first sensing lines TLX1 to TLX6 is not limited thereto, and all of the first sensing lines TLX1 to TLX6 may be disposed on the left side of the non-display region NDA, or all of the first sensing lines TLX1 to TLX6 may be disposed on the right side of the non-display region NDA.

The first sensing lines TLX1 to TLX6 may each extend toward the second base region AA2 via the bending region BA from the first base region AA1. The first sensing lines TLX1 to TLX6 may each be electrically connected to the sensing pads I-PD disposed on the second base region AA2.

The second sensing lines TLY1 to TLY4 may be disposed on the non-display region NDA and be electrically connected to the second sensing electrodes TEY1 to TEY4, respectively. Some of the second sensing lines TLY1 to TLY4 may be disposed adjacent to a left side of the non-display region NDA, and a remaining may be disposed adjacent to a right side of the non-display region NDA. For example, in the first direction DR1, the second sensing lines TLY1 and TLY2 electrically connected to the second sensing electrodes TEY1 and TEY2 disposed on the left side of the second sensing electrodes TEY1 to TEY4 may be disposed adjacent to the left side of the first base region AA1, and the second sensing lines TLY3 and TLY4 electrically connected to the second sensing electrodes TEY3 and TEY4 disposed on the right side may be disposed adjacent to the right side of the first base region AA1. However, the arrangement of the second sensing lines TLY1 to TLY4 is not limited thereto.

The second sensing lines TLY1 to TLY4 may each extend toward the second base region AA2 via the bending region BA from a region adjacent to a lower end of the first base region AA1. The second sensing lines TLY1 to TLY4 may each be electrically connected to the sensing pads I-PD disposed in the second base region AA2.

Some of the sensing pads I-PD may be disposed in a region adjacent to the left side of the second base region AA2 in the first direction DR1, and a remaining may be disposed in a region adjacent to the right side of the second base region AA2. For example, the sensing pads I-PD may be divided into two groups spaced apart from each other with the display pad region PD-A between the two groups of sensing pads I-PD. However, the arrangement of the sensing pads I-PD is not limited thereto.

The sensing pads I-PD and the display pads D-PD (see FIG. 4) may be disposed at a same layer. The sensing pads I-PD may be disposed at a different layer from the first and second sensing lines TLX1 to TLX6 and TLY1 to TLY4 and connected to the first and second sensing lines TLX1 to TLX6 and TLY1 to TLY4 through a contact hole. However, the embodiment of the disclosure is not limited thereto, and the sensing pads I-PD may also be disposed at a different layer from the display pads D-PD (see FIG. 4). For example, the sensing pads I-PD and the first and second sensing lines TLX1 to TLX6 and TLY1 to TLY4 may be formed at a same layer and may be integral with each other.

The first and second sensing lines TLX1 to TLX6 and TLY1 to TLY4 may be disposed on an upper portion of the components of the display panel DP (see FIG. 4) on a region corresponding to the non-display region NDA of the base substrate BS. Accordingly, the first and second sensing lines TLX1 to TLX6 and TLY1 to TLY4 may overlap the components of the display panel DP (see FIG. 4) in the bending region BA and the second base region AA2.

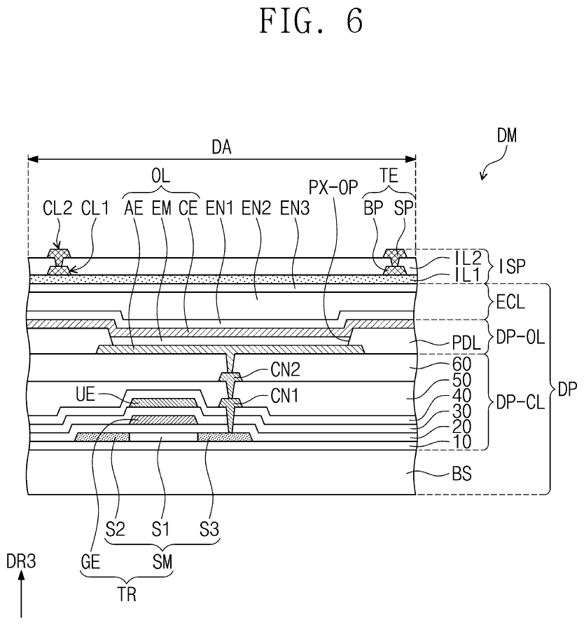

FIG. 6 is a schematic cross-sectional view of a display module DM according to an embodiment of the disclosure. FIG. 6 shows, as an example, a cross-section of the pixel PX (see FIG. 4) disposed in a display region DA.

Referring to FIG. 6, the display module DM may include a display panel DP and an input sensing unit ISP disposed on the display panel DP. The above descriptions may apply equally to respective components.

As described above in FIG. 3, the display panel DP may include a base substrate BS, a circuit element layer DP-CL, a light emitting element layer DP-OL, and an encapsulation layer ECL.

The base substrate BS has insulating properties and may provide a base surface on which components of the display module DM are disposed. The base substrate BS may flexible so as to be bendable. As described above, the base substrate BS may include a first base region AA1 (see FIG. 4), a bending region BA (see FIG. 4), and a second base region AA2 (see FIG. 4), and the bending region BA (see FIG. 4) of the base substrate BS may be bent at a curvature.

The circuit element layer DP-CL may include insulating layers 10 to 60 disposed on the base substrate BS, a transistor TR of the pixel PX (see FIG. 4), an upper electrode UE, and connection electrodes CN1 and CN2. The insulating layers 10 to 60 may include first to sixth insulating layers 10 to 60 sequentially stacked on each other in a thickness direction on the base substrate BS. However, the embodiments of the insulating layers 10 to 60 included in the circuit element layer DP-CL are not limited thereto and may vary depending on the configuration or manufacturing process of the circuit element layer DP-CL.

The first insulating layer 10 may be disposed on the base substrate BS. The first insulating layer 10 may be provided as a barrier layer and/or buffer layer that prevents foreign material from entering from the outside. The first insulating layer 10 may enhance the bonding strength between the base substrate BS and a semiconductor pattern SM and/or a conductive pattern of the circuit element layer DP-CL. The first insulating layer 10 may include at least one of a silicon oxide layer or a silicon nitride layer. In an embodiment, the first insulating layer 10 may include silicon oxide layers and silicon nitride layers that are alternately stacked on each other.

The pixel PX (see FIG. 4) may be disposed on the base substrate BS. The pixel PX (see FIG. 4) may be disposed corresponding to the display region DA. The pixel PX (see FIG. 4) may include the transistor TR and a light emitting element OL.

The transistor TR may include a semiconductor pattern SM and a gate electrode GE. The semiconductor pattern SM may be disposed on the first insulating layer 10. The semiconductor pattern SM may include a channel S1, a source S2, and a drain S3. The semiconductor pattern SM may include a silicon semiconductor, and may include a single-crystal silicon semiconductor, a poly-silicon semiconductor, or an amorphous silicon semiconductor. The embodiment of the disclosure is not limited thereto, and the semiconductor pattern SM may include an oxide semiconductor. The semiconductor pattern SM according to an embodiment of the disclosure may be formed of various materials as long as the materials have semiconductor properties, and is not limited to an embodiment.

The semiconductor pattern SM may include multiple regions having different electrical properties depending on the presence or absence of doping or reduction. For example, the semiconductor pattern SM may include a region that is highly conductive due to doping or reduction of a metal oxide, and the highly conductive region may serve as an electrode for a transistor TR or a signal line. This may correspond to the source S2 and drain S3 of the transistor TR. The semiconductor pattern SM may include a region that is less conductive due to an absence of doping, and this may correspond to the channel S1 (or active region) of the transistor TR.

The second insulating layer 20 may be disposed on the first insulating layer 10 and may cover (or overlap) the semiconductor pattern SM. The gate electrode GE may be disposed on the second insulating layer 20. The second insulating layer 20 may be disposed between the semiconductor pattern SM and the gate electrode GE of the transistor TR. The gate electrode GE may overlap the channel S1 of the semiconductor pattern SM in a plan view. The gate electrode GE may serve as a mask in the doping process of the semiconductor pattern SM. The gate electrode GE may include heat-resistant molybdenum (Mo), an alloy containing molybdenum, titanium (Ti), an alloy containing titanium, and the like, but is not limited thereto.

The structure of the transistor TR shown in FIG. 6 is presented as an example, and the source S2 or the drain S3 of the transistor TR may be electrodes formed independently from the semiconductor pattern SM. The source S2 and the drain S3 may contact the semiconductor pattern SM or be connected to the semiconductor pattern SM through a contact hole formed in an insulating layer. The gate electrode GE may be disposed below the semiconductor pattern SM. The transistor TR according to an embodiment of the disclosure may be formed in various structures and is not limited to an embodiment.

The second insulating layer 20 and the third to sixth insulating layers 30 to 60, which will be described later, may include at least one of an inorganic layer or an organic layer. For example, the inorganic layer may include at least one of aluminum oxide, titanium oxide, silicon oxide, silicon oxynitride, zirconium oxide, or hafnium oxide. The organic layer may include at least one of an acryl-based resin, a methacrylate-based resin, polyisoprene, a vinyl-based resin, an epoxy-based resin, a urethane-based resin, a cellulose-based resin, a siloxane-based resin, a polyamide-based resin, or a perylene-based resin.

The third insulating layer 30 may be disposed on the second insulating layer 20 and may cover (or overlap) the gate electrode GE. The upper electrode UE may be disposed on the third insulating layer 30. The upper electrode UE may overlap the gate electrode GE in a plan view, and the gate electrode GE and the upper electrode UE overlapping each other may form a capacitor.

The fourth insulating layer 40 may be disposed on the third insulating layer 30 and may cover (or overlap) the upper electrode UE. The connection electrodes CN1 and CN2 may include a first connection electrode CN1 and a second connection electrode CN2. The first connection electrode CN1 may be disposed on the fourth insulating layer 40. The fifth insulating layer 50 may be disposed on the fourth insulating layer 40 and may cover (or overlap) the first connection electrode CN1. The second connection electrode CN2 may be disposed on the fifth insulating layer 50. The sixth insulating layer 60 may be disposed on the fifth insulating layer 50 and may cover (or overlap) the second connection electrode CN2. In an embodiment, at least one of the fifth insulating layer 50 and the sixth insulating layer 60 may include an organic layer and may cover (or overlap) a step between components disposed below the at least one of the fifth insulating layer 50 and the sixth insulating layer 60 and provide a substantially flat upper surface.

The first connection electrode CN1 may be electrically connected to the semiconductor pattern SM through a contact hole passing through the second to fourth insulating layers 20 to 40. The second connection electrode CN2 may be electrically connected to the first connection electrode CN1 through a contact hole passing through the fifth insulating layer 50.

The first connection electrode CN1 and the second connection electrode CN2 may each include a conductive material. The first connection electrode CN1 and the second connection electrode CN2 may each include gold, silver, copper, aluminum, platinum, molybdenum, titanium, or an alloy thereof. At least one of the first connection electrode CN1 or the second connection electrode CN2 may include conductive layers having a multi-layer structure. For example, at least one of the first connection electrode CN1 or the second connection electrode CN2 may have a three-layer structure of titanium/aluminum/titanium. However, the embodiment of the disclosure is not limited thereto.

Depending on an embodiment of the circuit element layer DP-CL, at least one of the first connection electrode CN1 or the second connection electrode CN2 may not be provided. For example, depending on an embodiment of the circuit element layer DP-CL, additional connection electrodes may be further disposed to connect the transistor TR and the light emitting element OL. Depending on the number of insulating layers disposed between the light emitting element OL and the transistor TR, a method of electrically connecting the light emitting element OL and the transistor TR may be variously changed, and is not limited to an embodiment.

The light emitting element layer DP-OL may include the light emitting element OL and a pixel defining film PDL. The light emitting element OL and the pixel defining film PDL may be disposed on the sixth insulating layer 60. The light emitting element OL may include a first electrode AE, an emission layer EM, and a second electrode CE.

The first electrode AE may be electrically connected to the second connection electrode CN2 through a contact hole passing through the sixth insulating layer 60. The first electrode AE may be electrically connected to the transistor TR through the first and second connection electrodes CN1 and CN2.

A pixel opening PX-OP exposing at least a portion of the first electrode AE may be defined in the pixel defining film PDL. A portion of the first electrode AE exposed from the pixel defining film PDL may correspond to a light emitting region. The pixel defining film PDL may include an inorganic layer, an organic layer, or a composite material layer. Depending on embodiments, the pixel defining film PDL may further include a black pigment or a black dye.

The emission layer EM may be disposed on the first electrode AE. The emission layer EM may provide light of a color. The emission layer EM may be disposed corresponding to the pixel opening PX-OP of the pixel defining film PDL. The light emitting element OL and the pixel opening PX-OP may be provided in plurality, and the emission layers EM of the light emitting elements OL may each be disposed corresponding to the pixel opening PX-OP and provided spaced apart from each other in a pattern form. However, the embodiment of the disclosure is not limited thereto, and the emission layers EM of the light emitting elements OL may be formed as a single-body common layer.

The second electrode CE may be disposed on the emission layer EM and the pixel defining film PDL. The second electrode CE may be provided as a common electrode commonly disposed in the pixels PX (see FIG. 4).

The light emitting element OL may further include at least one of a hole control region disposed between the first electrode AE and the emission layer EM or an electron control region disposed between the emission layer EM and the second electrode CE. The hole control region may include at least one of a hole generation layer, a hole transport layer, or an electron blocking layer, and the electron control region may include at least one of an electron generation layer, an electron transport layer, or a hole blocking layer.

The encapsulation layer ECL may be disposed on the light emitting element layer DP-OL. The encapsulation layer ECL may be disposed on the light emitting element OL and the pixel defining film PDL to seal the light emitting element OL. The encapsulation layer ECL may include at least one of an inorganic film or an organic film. In the embodiment, the encapsulation layer ECL may include a first inorganic film EN1, a second inorganic film EN3, and an organic film EN2 disposed between the first and second inorganic films EN1 and EN3. However, the configuration of the encapsulation layer ECL is not limited thereto as long as it may seal the light emitting element OL.

The first inorganic film EN1 may be disposed on the second electrode CE, and the organic film EN2 and the second inorganic film EN3 may be sequentially disposed on the first inorganic film EN1 in a thickness direction of the display panel DP. The first and second inorganic films EN1 and EN3 may protect the light emitting element OL from moisture or oxygen entering from the outside. For example, the first and second inorganic films EN1 and EN3 may each include at least one of silicon nitride, silicon oxynitride, silicon oxide, titanium oxide, or aluminum oxide. However, materials of the first and second inorganic films EN1 and EN3 are not limited to the above examples. The organic film EN2 may prevent foreign material from entering into the light emitting element OL and cover (or overlap) steps between components disposed below the organic film EN2. For example, the organic film EN2 may include an acryl-based organic material. However, the materials of the organic film EN2 are not limited to the above examples.

The input sensing unit ISP may be disposed on the display panel DP. The input sensing unit ISP may include a base layer IL1, a first sensing insulating layer IL2, a first sensing conductive layer CL1, and a second sensing conductive layer CL2. The input sensing unit ISP may further include a second sensing insulating layer IL3 (see FIG. 3) as shown in FIG. 3. The above descriptions may apply equally to respective components.

The base layer IL1 may be in contact with an uppermost layer of the encapsulation layer ECL. For example, the base layer IL1 may be in contact with the second inorganic film EN3 of the encapsulation layer ECL. The base layer IL1 of the input sensing unit ISP may be formed on (e.g., directly on) a base surface provided by the encapsulation layer ECL. However, the embodiment of the disclosure is not limited thereto, and depending on embodiments, the base layer IL1 may not be provided, in which case, the first sensing conductive layer CL1 of the input sensing unit ISP may be in contact with the encapsulation layer ECL.

The first sensing conductive layer CL1 may be disposed on the base layer IL1, and the second sensing conductive layer CL2 may be disposed on the first sensing insulating layer IL2. The first sensing conductive layer CL1 and the second sensing conductive layer CL2 may form a sensing electrode TE. The sensing electrode TE may correspond to one of the first and second sensing electrodes TEX and TEY (see FIG. 5) described above. For example, the first sensing conductive layer CL1 may include a connection pattern BP of the sensing electrode TE, and the second sensing conductive layer CL2 may include a sensing pattern SP of the sensing electrode TE. However, the embodiment of the disclosure is not limited thereto, and the first sensing conductive layer CL1 may include a sensing pattern SP, and the second sensing conductive layer CL2 may include a connection pattern BP.

The connection pattern BP may correspond to the first connection pattern BP1 (see FIG. 5) or the second connection pattern BP2 (see FIG. 5) described above, and the sensing pattern SP may correspond to the first sensing pattern SP1 (see FIG. 5) or the second sensing pattern SP2 (see FIG. 5) described above. The connection pattern BP may be disposed at a different layer from the sensing pattern SP and may be connected to the sensing pattern SP through a contact hole passing through the first sensing insulating layer IL2. However, the embodiment of the disclosure is not limited thereto, and the connection pattern BP and the sensing pattern SP may be disposed at a same layer and formed as a single body (or be integral with each other).

The sensing electrode TE may be a mesh-shaped pattern and may be disposed corresponding to a region where the pixel defining film PDL is disposed. However, the embodiment of the disclosure is not limited thereto, and the sensing electrode TE may be provided as a single-shaped pattern overlapping the light emitting element OL, and the sensing electrode TE may include a transparent conductive material.

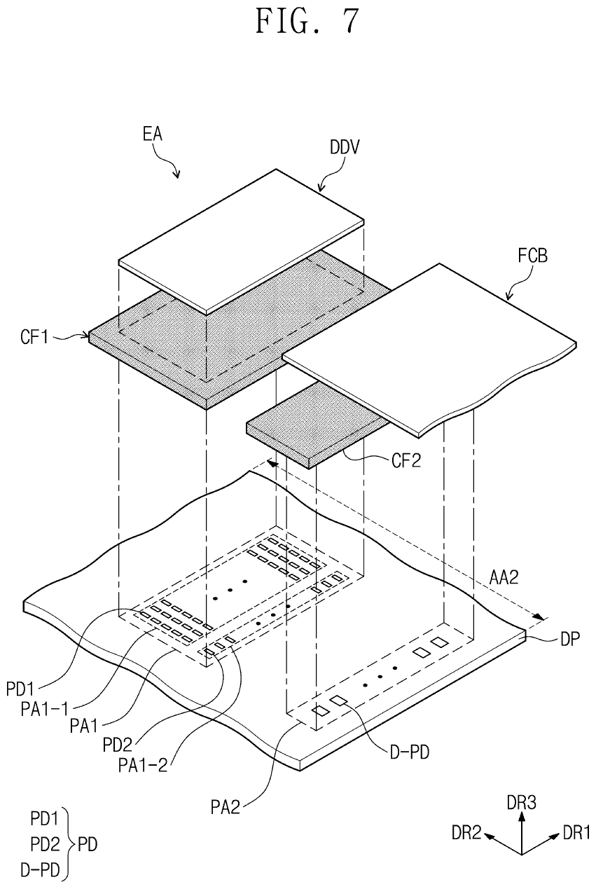

FIG. 7 is a schematic perspective view of an electronic device EA according to an embodiment of the disclosure. FIG. 7 briefly shows some components of an electronic device EA disposed corresponding to the second base region AA2.

The second base region AA2 corresponds to a portion of the non-display region NDA (see FIG. 4). As shown in FIG. 7, of the non-display region NDA or the second base region AA2, a region where the data driver DDV is bonded may be defined as a first pad region PA1, and a region where the flexible circuit board FCB is bonded may be defined as a second pad region PA2. In an embodiment, the data driver DDV and the flexible circuit board FCB may be collectively referred to as electronic component, and the electronic component may include a bump electrode disposed in the pad regions PA1 and PA2.

The data driver DDV may be bonded to the first pad region PA1 through a first adhesive layer CF1, and the flexible circuit board FCB may be bonded to the second pad region PA2 through a second adhesive layer CF2. The first adhesive layer CF1 and the second adhesive layer CF2 may each include a synthetic resin having adhesive properties. The first adhesive layer CF1 and the second adhesive layer CF2 may each be a non-conductive film (NCF). For example, the first adhesive layer CF1 and the second adhesive layer CF2 may each be an adhesive resin containing no conductive particles.

However, the embodiment of the disclosure is not limited thereto, and in an embodiment, at least one of the first adhesive layer CF1 or the second adhesive layer CF2 may not be provided. For example, the data driver DDV and the flexible circuit board FCB may be bonded to the first pad region PA1 and the second pad region PA2, respectively, through ultrasonic bonding.

The display panel DP may include multiple pads PD. The pads PD may include first signal pads PD1, second signal pads PD2, and display pads D-PD. The first signal pads PD1, the second signal pads PD2, and the display pads D-PD may be pads disposed in a signal transmission path.

The first signal pads PD1 may be disposed corresponding to an output pad of the data driver DDV and may be input pads receiving signals from the data driver DDV. The second signal pads PD2 may be disposed corresponding to an input pad of the data driver DDV and may be output pads outputting signals to the data driver DDV. The display pads D-PD may be panel input pads receiving signals from the flexible circuit board FCB.

The first signal pads PD1 may each be electrically connected to the pixels PX (see FIG. 4) of the display panel DP through a signal line, and may transmit and receive signals to and from the pixels PX (see FIG. 4). The second signal pads PD2 may each be electrically connected to a corresponding display pad D-PD among the display pads D-PD through a signal line, and the display pads D-PD and the second signal pads PD2 that are electrically connected may transmit and receive signals.

The first pad region PA1 may include a first sub pad region PA1-1 and a second sub pad region PA1-2. The first sub pad region PA1-1 may be defined as a region where the first signal pads PD1 are disposed. The second sub pad region PA1-2 may be defined as a region where the second signal pads PD2 are disposed.

The first signal pads PD1 may be arranged (or disposed) in the first direction DR1 and the second direction DR2 in the first sub pad region PA1-1. Among the first signal pads PD1, the first signal pads PD1 arranged (or disposed) in the first direction DR1 may be defined as a pad row. FIG. 7 shows, as an example, that five rows of pads are disposed in the second direction DR2. The arrangement of the first signal pads PD1 is not limited to thereto.

The second signal pads PD2 may be arranged (or disposed) in the first direction DR1 in the second sub pad region PA1-2. The second signal pads PD2 may be disposed in a single pad row. However, the arrangement of the second signal pads PD2 is not limited to thereto.

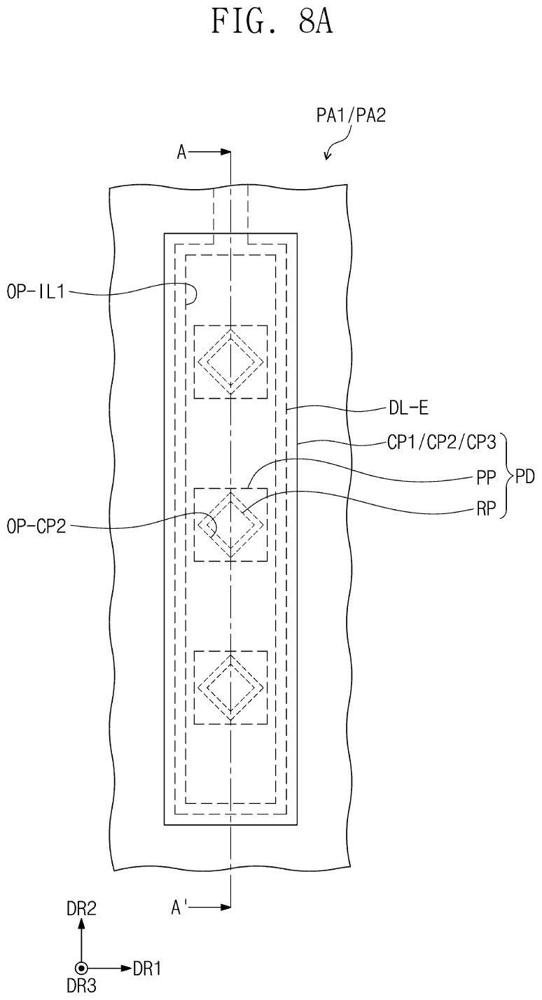

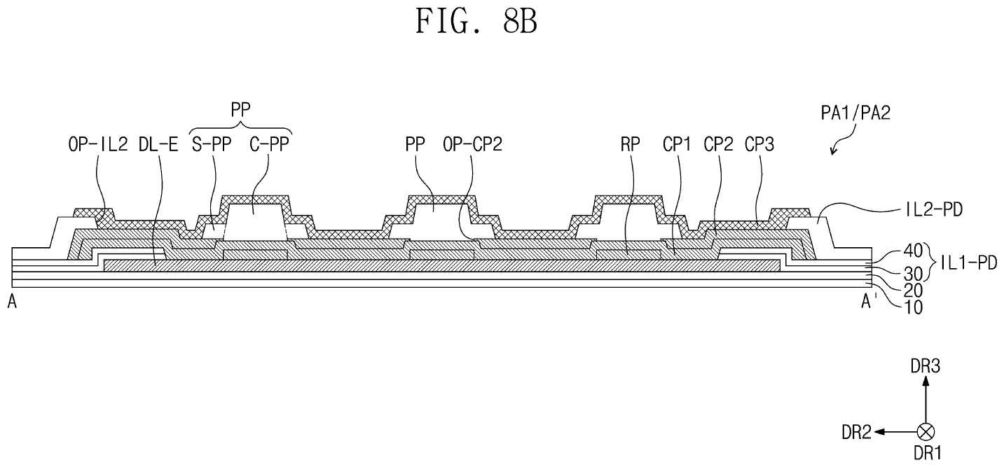

FIG. 8A is a schematic plan view of pad regions PA1 and PA2 according to an embodiment of the disclosure. FIG. 8B is a cross-sectional view of pad regions PA1 and PA2 according to an embodiment of the disclosure.

FIG. 8A is a schematic plan view showing an enlarged portion where a signal pad PD (e.g., single signal pad PD) is disposed, in the pad regions PA1 and PA2 according to an embodiment of the disclosure. FIG. 8B is a cross-sectional view of pad regions PA1 and PA2 corresponding to line A-A′ of FIG. 8A.

The signal pad PD shown in FIGS. 8A and 8B may be one of the first signal pad PD1, the second signal pad PD2, and the display pad D-PD described with reference to FIG. 7. Although the data line DL1 to DLn (see FIG. 4) including an end portion DL-E is shown as an example of the signal line, the embodiment of the disclosure is not limited thereto. The signal line may be another signal line other than the data line DL1 to DLn (see FIG. 4).

Hereinafter, the pad regions PA1 and PA2 will be described, focusing on the first sub pad region PA1-1 (see FIG. 7) where the data lines DL1 to DLn (see FIG. 4) are disposed. The description of the first sub pad region PA1-1 (see FIG. 7) may equally apply to the second sub pad region PA1-2, except that connection signal lines are disposed instead of the data lines DL1 to DLn (see FIG. 4).

Referring to FIGS. 8A and 8B, the signal pad PD may include a first conductive pattern CP1, a second conductive pattern CP2, a third conductive pattern CP3, and at least one insulating pattern PP. FIG. 8A shows, as an example, a structure in which the first conductive pattern CP1, the second conductive pattern CP2, and the third conductive pattern CP3 are all placed at the same location, having the same size of area. The signal pad PD may further include pad insulating layers IL1-PD and IL2-PD. For example, the signal pad PD may further include a first pad insulating layer IL1-PD and a second pad insulating layer IL2-PD. For convenience of description, the first and second pad insulating layers IL1-PD and IL2-PD are not provided in the schematic plan view of FIG. 8A, and only a first insulating layer opening OP-IL1 defined in the first pad insulating layer IL1-PD is shown.

The signal pad PD may further include a reinforcing pattern RP. To show a structure in which the reinforcing pattern RP is disposed inside an opening OP-CP2, in FIG. 8A, the reinforcing pattern RP is shown to be spaced apart from the opening OP-CP2 and have a smaller area than the opening OP-CP2, but in embodiments of the disclosure, as shown in FIG. 8B, the reinforcing pattern RP may be disposed to contact the opening OP-CP2 and fill the opening OP-CP2.

In FIG. 8A, the insulating pattern PP is shown to cover (or overlap) the entire opening OP-CP2 in a plan view, but is not limited thereto, and a structure in which the opening OP-CP2 is partially covered (or overlapped) may be formed. At least a portion of the insulating pattern PP may not overlap the opening OP-CP2 to define a side portion S-PP, which will be described later, and pressure applied in a bonding process by the side portion S-PP is not dispersed, but may be concentrated on the third conductive pattern CP3 disposed on an upper portion of a central portion C-PP of the insulating pattern PP.

The end portion DL-E of the data line may be disposed in the pad regions PA1 and PA2. Herein, the end portion DL-E of the data line may be referred to as a portion of the signal line.

In a plan view, the end portion DL-E of the data line may be in the form extending in the second direction DR2. For example, the end portion DL-E may have a length or width in the second direction DR2 greater than a length or width in the first direction DR1. The end portion DL-E of the data line and the gate electrode GE (see FIG. 6) of the transistor TR (see FIG. 6) disposed in the display region DA (see FIG. 6) described above may be formed from a same layer. For example, the end portion DL-E of the data line may be disposed on the second insulating layer 20. The end portion DL-E of the data line and the gate electrode GE (see FIG. 6) may include a same material. For example, the end portion DL-E of the data line may include molybdenum (Mo), an alloy containing molybdenum, titanium (Ti), an alloy containing titanium, or a combination thereof. The end portion DL-E of the data line may be formed in the same process (e.g., patterning process) as the gate electrode GE (see FIG. 6). The end portion DL-E of the data line may have the same thickness as the gate electrode GE (see FIG. 6).

However, the position of the end portion DL-E is not limited thereto. The end portion DL-E and the upper electrode UE shown in FIG. 6 may be formed from the same layer or at the same layer, may include the same material, and may have a same stack structure. For example, some of multiple signal lines may be formed through the same process as the gate electrode GE (see FIG. 6), and others may be formed through the same process as the upper electrode UE (see FIG. 6).

The data lines DL1 to DLn (see FIG. 4) may be disposed on a layer (i.e., a single layer), and may be integral with each other, but are not limited thereto. One of the data line DL1 to DLn (see FIG. 4) may include multiple portions disposed at different layers.

The first conductive pattern CP1 may be disposed on the end portion DL-E of the data line. In a plan view, the first conductive pattern CP1 may overlap the end portion DL-E of the data line. In a plan view, the end portion DL-E of the data line may be disposed inside the first conductive pattern CP1, but is not limited thereto.

The first conductive pattern CP1 may be connected to the end portion DL-E of the data line DL1 to DLn (see FIG. 4) through the first insulating layer opening OP-IL1 defined in the first pad insulating layer IL1-PD. Herein, the insulating layers disposed between the end portion DL-E and the first conductive pattern CP1 may be defined as the first pad insulating layer IL1-PD. In the embodiment, the third and fourth insulating layers 30 and 40 may be defined as the first pad insulating layer IL1-PD. The stack structure of the first pad insulating layer IL1-PD may vary depending on the stack structure of the circuit element layer DP-CL (see FIG. 6). In an embodiment, the first insulating layer opening OP-IL1 may be defined by a greater number of insulating layers than the third and fourth insulating layers 30 and 40, or may be defined by a smaller number of insulating layers. The first conductive pattern CP1 and the end portion DL-E may be distinguished by the first pad insulating layer IL1-PD (e.g., the third and fourth insulating layers 30 and 40) disposed between the first conductive pattern CP1 and the end portion DL-E.

The first conductive pattern CP1 and the first connection electrode CN1 (see FIG. 6) connected to the transistor TR (see FIG. 6) of the display region DA (see FIG. 6) described above may be formed from the same layer or at the same layer. For example, the first conductive pattern CP1 may be disposed on the fourth insulating layer 40. The first conductive pattern CP1 and the first connection electrode CN1 (see FIG. 6) may include a same material. The first conductive pattern CP1 and the first connection electrode CN1 (see FIG. 6) may be formed by the same process or from the same layer. The first conductive pattern CP1 may have a single-layer structure or a multi-layer structure, and may have the same stack structure as the first connection electrode CN1 (see FIG. 6). For example, the first conductive pattern CP1 may have a three-layer structure of titanium/aluminum/titanium. The first conductive pattern CP1 may have the same thickness as the first connection electrode CN1 (see FIG. 6). The first conductive pattern CP1 may have a thickness in a range of about 6000 Å to about 9000 Å. For example, the first conductive pattern CP1 may have a thickness in a range of about 7000 Å to about 8500 Å.

The second conductive pattern CP2 may be disposed on the first conductive pattern CP1. The second conductive pattern CP2 and the first conductive pattern CP1 may be distinguished by a boundary line observed in the cross-section, resulting from their formation in different processes. The second conductive pattern CP2 may contact the first conductive pattern CP1 and be electrically connected to the first conductive pattern CP1. In a plan view, the second conductive pattern CP2 may overlap the first conductive pattern CP1. In a plan view, the first conductive pattern CP1 may be disposed inside the second conductive pattern CP. However, the embodiment of the disclosure is not limited thereto, and for example, in a plan view, the second conductive pattern CP2 may be disposed inside the first conductive pattern CP1, or may be disposed at the same location as the first conductive pattern CP1.

The second conductive pattern CP2 and the second connection electrode CN2 (see FIG. 6) connected to the first connection electrode CN1 (see FIG. 6) of the display region DA (see FIG. 6) described above may be formed from the same layer or formed at the same layer. The second conductive pattern CP2 and the second connection electrode CN2 (see FIG. 6) may include a same material. The second conductive pattern CP2 and the second connection electrode CN2 (see FIG. 6) may be formed by the same process or from the same layer. The second conductive pattern CP2 may have a single-layer structure or a multi-layer structure, and may have the same stack structure as the second connection electrode CN2 (see FIG. 6). For example, the second conductive pattern CP2 may have a three-layer structure of titanium/aluminum/titanium. The second conductive pattern CP2 may have the same thickness as the second connection electrode CN2 (see FIG. 6). The second conductive pattern CP2 may have a thickness in a range of about 6000 Å to about 9000 Å. For example, the second conductive pattern CP2 may have a thickness in a range of about 7000 Å to about 8500 Å.

The signal pad PD may further include a pad insulating layer disposed between the first conductive pattern CP1 and the second conductive pattern CP2 and having an insulating layer opening that exposes the first conductive pattern CP1 defined therein. For example, the pad insulating layer disposed between the first conductive pattern CP1 and the second conductive pattern CP2 may be a layer in which the fifth insulating layer 50 of the display region DA (see FIG. 6) described above is disposed to extend to the pad regions PA1 and PA2.

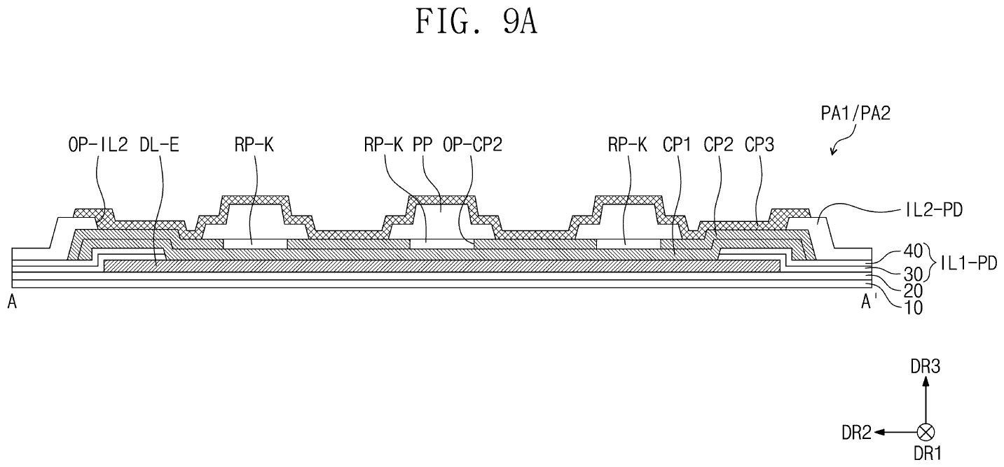

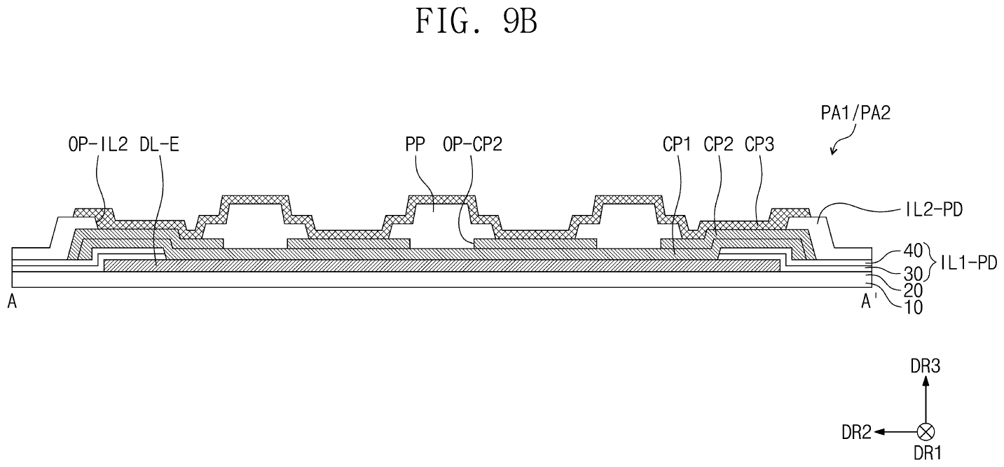

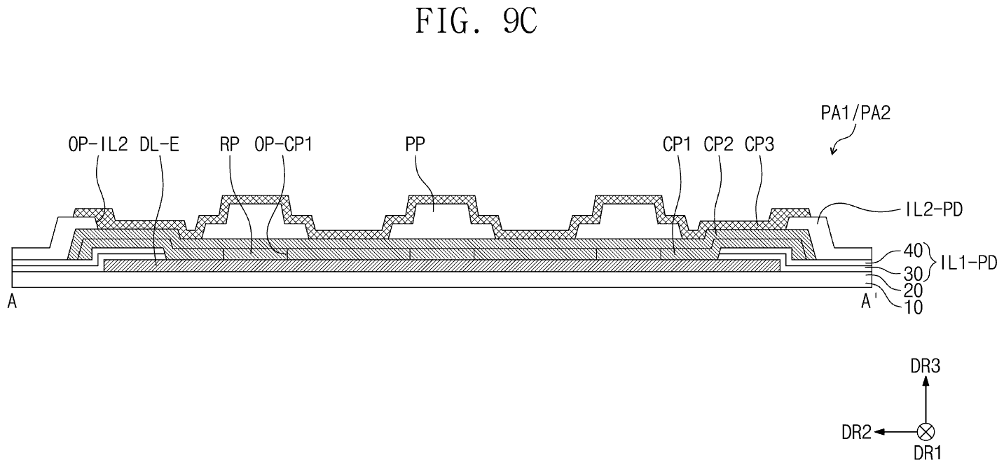

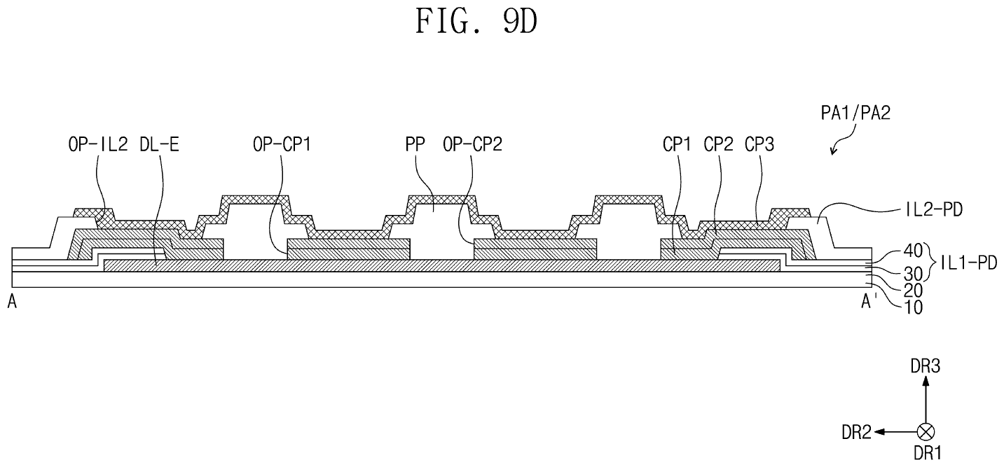

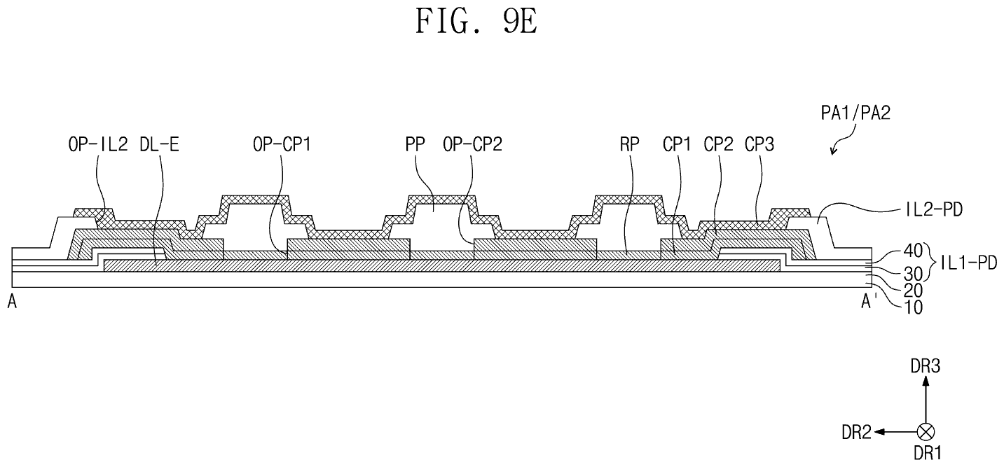

At least one of the first conductive pattern CP1 or the second conductive pattern CP2 may have an opening defined therein. FIGS. 8A and 8B show, as an example, a structure in which an opening OP-CP2 is defined in the second conductive pattern CP2. The opening OP-CP2 defined in the second conductive pattern CP2 may be referred to as a second opening OP-CP2 to be differentiated from the opening OP-CP1 (see FIG. 9C) defined in the first conductive pattern CP1.

In a plan view, the opening OP-CP2 may be defined at a position overlapping the insulating pattern PP. In a plan view, the opening OP-CP2 may be defined as having an area smaller than an area of the insulating pattern PP. The opening OP-CP2 overlapping the insulating pattern PP may be defined in the second conductive pattern CP2 disposed below the insulating pattern PP, and accordingly, the issue of pressure applied in a bonding process dispersing downward in case that both the first and second conductive patterns CP1 and CP2 are disposed below and overlapped by the insulating pattern PP may be prevented.

The signal pad PD may further include a reinforcing pattern RP disposed in the opening OP-CP2. The reinforcing pattern RP may be disposed below the insulating pattern PP. In a plan view, the reinforcing pattern RP may be disposed to overlap the insulating pattern PP. The reinforcing pattern RP may have a greater hardness than the insulating pattern PP. The reinforcing pattern RP may include a metal. For example, the reinforcing pattern RP may include molybdenum (Mo). The reinforcing pattern RP may be disposed to overlap the insulating pattern PP, and thus firmly support the insulating pattern PP, thereby preventing the pressure applied in a bonding process from dispersing downward. The reinforcing pattern RP may not be disposed to overlap an entirety of the conductive patterns CP1 and CP2 of the signal pad PD, but may be disposed only corresponding to the portion where the insulating pattern PP is disposed, and may thus support the insulating pattern PP firmly to prevent the pressure applied in a bonding process from dispersing.

The reinforcing pattern RP and at least an electrode disposed between the transistor TR (see FIG. 6) and the first connection electrode CN1 (see FIG. 6) of the display region DA (see FIG. 6) may be formed by the same process or from the same layer. For example, the reinforcing pattern RP and the upper electrode UE of FIG. 6 may be formed by the same process or from the same layer. Accordingly, the reinforcing pattern RP and the upper electrode UE of FIG. 6 may include a same material and may have a same thickness. The reinforcing pattern RP may be formed by modifying a mask pattern of a typical process without adding a separate mask process.

As shown in FIG. 8B, the reinforcing pattern RP may be disposed below the first conductive pattern CP1 in case that no opening is defined in the first conductive pattern CP1. In contrast, in case that an opening is defined in the first conductive pattern CP1 and no opening is defined in the second conductive pattern CP2, the reinforcing pattern RP may be disposed below the second conductive pattern CP2.

The second pad insulating layer IL2-PD and the base layer IL1 of the input sensing unit ISP (see FIG. 6) described above may include a same material. The second pad insulating layer IL2-PD may be formed by the same process or from the same layer as the base layer IL1. The second pad insulating layer IL2-PD may include an inorganic film. For example, the inorganic film may include at least one of aluminum oxide, titanium oxide, silicon oxide, silicon nitride, silicon oxynitride, zirconium oxide, hafnium oxide, or a combination thereof.

A second insulating layer opening OP-IL2 may be defined in the second pad insulating layer IL2-PD. The second insulating layer opening OP-IL2 may expose the second conductive pattern CP2. The third conductive pattern CP3 may be connected to the second conductive pattern CP2 through the second insulating layer opening OP-IL2.

The third conductive pattern CP3 may be disposed on the second conductive pattern CP2. In a plan view, the third conductive pattern CP3 may overlap the second conductive pattern CP2. In FIG. 8A, for convenience, the second conductive pattern CP2 and the third conductive pattern CP3 are shown to completely overlap in a plan view, but the second conductive pattern CP2 may be disposed inside the third conductive pattern CP3, or the third conductive pattern CP3 may be disposed inside the second conductive pattern CP2.

The third conductive pattern CP3 and the first sensing conductive layer CL1 or the second sensing conductive layer CL2 of the display region DA (see FIG. 6) described above may include a same material. For example, the third conductive pattern CP3 and the second sensing conductive layer CL2 of the display region DA (see FIG. 6) described above may include a same material. The third conductive pattern CP3 and the second sensing conductive layer CL2 may be formed in a same process from a same layer. The third conductive pattern CP3 and the second sensing conductive layer CL2 may have a same stack structure. The third conductive pattern CP3 and the second sensing conductive layer CL2 may have a same thickness.

The third conductive pattern CP3 may include a first layer disposed on the second conductive pattern CP2, a second layer disposed on the first layer, and a third layer disposed on the second layer. The second layer may be thicker than each of the first layer and the third layer. The second layer may have higher conductivity than the first layer and the third layer. The first layer and the third layer may include a same material. The second layer may include a different material from the first layer and the third layer. For example, the first layer and the third layer may include titanium (Ti), and the second layer may include aluminum (Al). In an embodiment, the first layer, second layer and the third layer described above may apply equally to the first conductive pattern CP1 and the second conductive pattern CP2. In case that pressure is applied in a bonding process, the third layer disposed on an uppermost portion of the third conductive pattern CP3 is stretched and torn due to the pressure. This exposes the second layer, which may then be connected to a bump electrode of an electronic component.

The insulating patterns PP may be disposed between the second conductive pattern CP2 and the third conductive pattern CP3. A lower surface of the insulating patterns PP may be in contact with the first conductive pattern CP1 or the second conductive pattern CP2, and a side surface and an upper surface of the insulating patterns PP may each be covered (or overlapped) by the third conductive pattern CP3. The insulating patterns PP may form a protrusion in the pad regions PA1 and PA2.

In a plan view, the insulating patterns PP may overlap each of the second conductive pattern CP2 and the third conductive pattern CP3. In the embodiment, the insulating patterns PP may be arranged (or disposed) in the second direction DR2. The insulating patterns PP may be spaced apart from each other in the second direction DR2. In a plan view, the insulating patterns PP may be disposed inside the second insulating layer opening OP-IL2. The insulating patterns PP may be disposed to overlap the opening OP-CP2 defined in the second conductive pattern CP2.

In FIGS. 8A and 8B, a structure in which three insulating patterns PP are disposed in a row is shown as an example, but the number and arrangement of the insulating patterns PP are not limited thereto. In FIG. 8A, a structure in which the insulating patterns PP are in the shape of a square in a plan view is shown as an example, but the embodiment of the disclosure is not limited thereto. The shapes of the insulating patterns PP in a plan view may be changed to polygons, circles, or ellipses, in addition to squares. The shapes of the insulating patterns PP are not limited to being the same.

An upper surface of the insulating pattern PP may include a step shape on a cross-section. For example, the insulating pattern PP may include a central portion C-PP overlapping the opening OP-CP2, and a side portion S-PP that does not overlap the opening OP-CP2. The central portion C-PP has a greater thickness than the side portion S-PP. The central portion C-PP may protrude further than the side portion S-PP in the third direction DR3 toward the third conductive pattern CP3. In a plan view, the side portion S-PP may be adjacent to the central portion C-PP and surround at least a portion of the central portion C-PP. The side portion S-PP may overlap each of the first conductive pattern CP1 and the second conductive pattern CP2.

The insulating pattern PP according to an embodiment of the disclosure includes the side portion S-PP that protrudes less than the central portion C-PP, and accordingly, the pressure applied in a bonding process may not be dispersed, but may be concentrated on the third conductive pattern CP3 disposed on the insulating pattern PP.

The insulating pattern PP may include a polymer. The insulating pattern PP may include a thermosetting polymer. However, the embodiment of the disclosure is not limited thereto, and the insulating pattern PP may also include a thermoplastic polymer.

In an embodiment, the insulating pattern PP may be formed through the same process as the first sensing insulating layer IL2 (see FIG. 6) of the input sensing unit ISP (see FIG. 6). Accordingly, an additional process for forming the insulating pattern PP may not be required.

In an embodiment, the insulating pattern PP may have a height in a range of about 1 μm to about 2 μm. The height of the insulating pattern PP may indicate a length of the third direction DR3 of the insulating pattern PP. For example, the insulating pattern PP may have a height in a range of about 1.3 μm to about 1.7 μm. In an embodiment, the insulating pattern PP may have a width of about 2 μm or greater. The width of the insulating pattern PP may indicate a length of the first direction DR1 or a length of the second direction DR2 of the insulating pattern PP. For example, the insulating pattern PP may have a width of about 3 μm or greater.

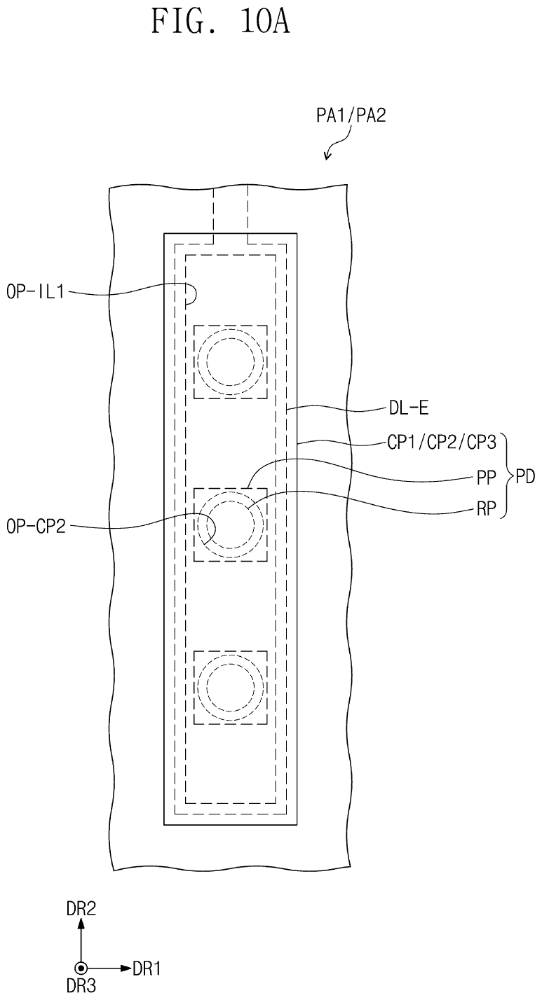

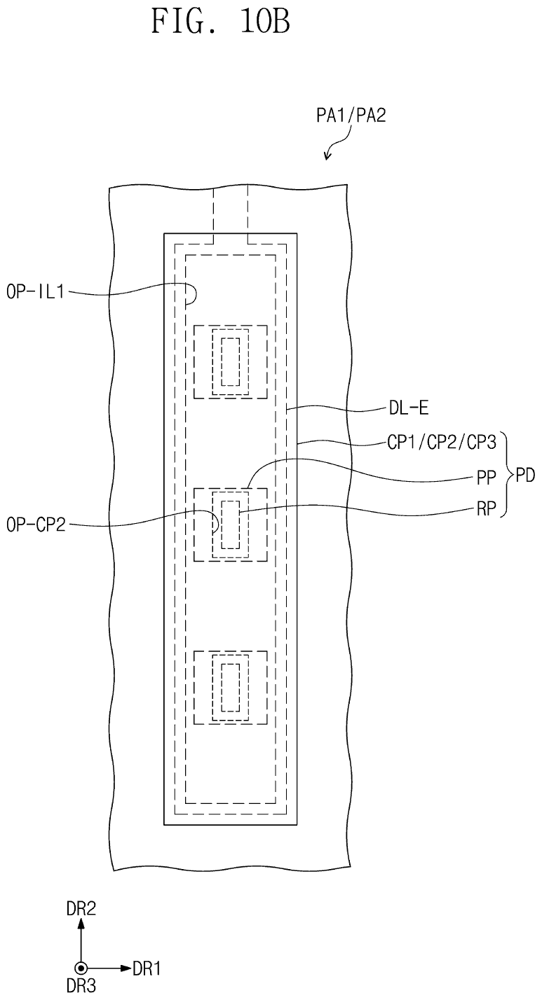

FIGS. 9A to 9E are each schematic cross-sectional views of pad regions PA1 and PA2 according to an embodiment of the disclosure. FIGS. 10A and 10B are each schematic cross-sectional views of pad regions PA1 and PA2 according to an embodiment of the disclosure.

FIGS. 9A to 10B each show other embodiments of positions corresponding to A-A′ of FIG. 8 for the structure of the signal pad PD disposed in the pad regions PA1 and PA2 according to an embodiment of the disclosure. The description given above with reference to the pad regions PA1 and PA2 of FIGS. 8A and 8B may equally apply to the pad regions PA1 and PA2 of FIGS. 9A to 10B.

Referring to FIG. 9A, a reinforcing pattern RP-K may be disposed on the first conductive pattern CP1. Of the first conductive pattern CP1 and the second conductive pattern CP2, an opening OP-CP2 may be defined only in the second conductive pattern CP2, and the reinforcing pattern RP-K may be disposed inside the opening OP-CP2 defined in the second conductive pattern CP2 and above the first conductive pattern CP1. The reinforcing pattern RP-K may be disposed (e.g., disposed directly) below the insulating pattern PP to support the insulating pattern PP, thereby preventing the pressure applied in a bonding process from dispersing.

The reinforcing pattern RP-K of FIG. 9A may be a metal material. However, the reinforcing pattern RP-K is not limited to a metal material, and may be any material having a greater hardness than the insulating pattern PP. Unlike the reinforcing pattern RP of FIG. 8B which is formed in the same process as any one of the electrodes disposed between the transistor TR (see FIG. 6) formed in the display region DA (see FIG. 6) and the first connection electrode CN1 (see FIG. 6), the reinforcing pattern RP-K may be formed by adding a separate process, thereby freely controlling locations and materials for forming the reinforcing pattern RP-K. For example, a material having a desired hardness may be formed as the reinforcing pattern RP-K at a desired position through an inkjet process.

Referring to FIG. 9B, of the first conductive pattern CP1 and the second conductive pattern CP2, an opening OP-CP2 may be defined only in the second conductive pattern CP2, and the insulating pattern PP may be disposed (e.g., disposed directly) on the first conductive pattern CP1, filling the inside of the opening OP-CP2 defined in the second conductive pattern CP2. The opening OP-CP2 of the second conductive pattern CP2 is defined at a position overlapping the insulating pattern PP, and thus, of the first conductive pattern CP1 and the second conductive pattern CP2, only the first conductive pattern CP1 is disposed below the insulating pattern PP, and accordingly, the first conductive pattern CP1 may support the insulating pattern PP to prevent the pressure applied in a bonding process from dispersing even without the reinforcing patterns RP and RP-K (see FIGS. 8B and 9A).

Referring to FIG. 9C, of the first conductive pattern CP1 and the second conductive pattern CP2, the opening OP-CP1 is defined only in the first conductive pattern CP1, and the reinforcing pattern RP may be disposed inside the opening OP-CP1 of the first conductive pattern CP1. The reinforcing pattern RP may be disposed to fill the opening OP-CP1 of the first conductive pattern CP1. The second conductive pattern CP2 may be disposed on the reinforcing pattern RP, and the insulating pattern PP may be disposed (e.g., disposed directly) on the second conductive pattern CP2. The reinforcing pattern RP may be disposed at a position overlapping the insulating pattern PP and the second conductive pattern CP2 may be disposed above the reinforcing pattern RP, and accordingly, the second conductive pattern CP2 may support the insulating pattern PP to prevent the pressure applied in a bonding process from dispersing.

Referring to FIGS. 9D and 9E, the openings OP-CP1 and OP-CP2 may be defined in the first conductive pattern CP1 and the second conductive pattern CP2, respectively. The opening OP-CP1 defined in the first conductive pattern CP1 may be referred to as a first opening, and the opening OP-CP2 defined in the second conductive pattern CP2 may be referred to as a second opening.

The openings OP-CP1 and OP-CP2 may be defined at positions overlapping the insulating pattern PP, but the openings OP-CP1 and OP-CP2 may not overlap the first and second conductive patterns CP1 and CP2, and thus, the pressure applied in a bonding process may not be dispersed. As in FIG. 9E, the reinforcing pattern RP, in case that disposed below the insulating pattern PP, may support the insulating pattern PP more firmly.

Referring to FIGS. 10A and 10B, the shape of the openings OP-CP1 and OP-CP2 defined in at least one of the first conductive pattern CP1 or the second conductive pattern CP2 in a plan view is not limited to the square shown in FIG. 8A, and may be polygons, circles, or ellipses other than squares. In FIG. 10A, a structure in which the openings OP-CP1 and OP-CP2 are circular in shape in a plan view is shown as an example. In FIG. 10B, a structure in which the openings OP-CP1 and OP-CP2 are rectangular in shape in a plan view is shown as an example.

The shape of the reinforcing pattern RP in a plan view is not limited to the square shown in FIG. 8A, and may be polygons, circles, or ellipses other than squares. In FIG. 10A, a structure in which the reinforcing pattern RP is circular in shape in a plan view is shown as an example. In FIG. 10B, a structure in which the reinforcing pattern RP is rectangular in shape in a plan view is shown as an example.

To show a structure in which the reinforcing pattern RP is disposed inside the openings OP-CP1 and OP-CP2, in FIGS. 10A and 10B, the reinforcing pattern RP is shown to be spaced apart from the openings OP-CP1 and OP-CP2 and have a smaller area than the openings OP-CP1 and OP-CP2, but in embodiments of the disclosure, the reinforcing pattern RP may be disposed to contact the openings OP-CP1 and OP-CP2, filling the openings OP-CP1 and OP-CP2.

In FIGS. 10A and 10B, the insulating pattern PP is shown to cover (or overlap) the entire openings OP-CP1 and OP-CP2 in a plan view, but is not limited thereto, and a structure in which the openings OP-CP1 and OP-CP2 are partially covered (or overlapped) may be formed. At least a portion of the insulating pattern PP may not overlap the openings OP-CP1 and OP-CP2 and may include the side portion S-PP described above in FIGS. 8A and 8B, and pressure applied in a bonding process by the side portion S-PP is not dispersed, but may be concentrated on the third conductive pattern CP3 disposed on an upper portion of the insulating pattern PP.

A display module according to an embodiment of the disclosure includes a signal pad including an opening in at least one of a first conductive pattern or a second conductive pattern, and may thus prevent the pressure applied in a bonding process from dispersing. The display module according to an embodiment of the disclosure includes a signal pad with a protruding central portion and a less protruding side portion of an insulating pattern, and may thus be better for supporting pressure applied in a bonding process. The signal pad of the display module according to an embodiment of the disclosure may include a reinforcing pattern having a greater hardness than the insulating pattern disposed below the insulating pattern corresponding to the insulating pattern, and may thus be better for supporting pressure applied in a bonding process due to the reinforcing pattern.

An electronic device including the display module according to an embodiment of the disclosure may have enhanced bonding reliability since the pressure applied in a bonding process between the display module and an electronic component is not dispersed but is concentrated on a third conductive pattern disposed on the insulating pattern.

As described above, a display module according to an embodiment of the disclosure may prevent pressure applied in a bonding process from dispersing as an opening is defined in at least one conductive layer disposed below an insulating pattern and corresponding to the insulating pattern of a signal pad. The insulating pattern of the signal pad may include a protruding central portion that may overlap the opening and a side portion that does not overlap the opening, and thus has a structure capable of supporting pressure. A reinforcing pattern may be disposed corresponding to the insulating pattern, and accordingly, the pressure applied in a bonding process may be effectively supported.

An electronic device including the display module according to an embodiment of the disclosure may exhibit excellent bonding reliability between the display module and an electronic component as the pressure may be concentrated on a conductive layer disposed above the insulating pattern in a bonding process between the signal pad of the display module and the electronic component.

Although the disclosure has been described with reference to an embodiment of the disclosure, it will be understood that the disclosure should not be limited to these embodiments but various changes and modifications may be made by those skilled in the art without departing from the spirit and scope of the disclosure. Hence, the technical scope of the disclosure is not limited to the detailed descriptions in the specification but should be determined only with reference to the claims.

What is claimed is:

1. A display module comprising:
a display panel including a display region, and a non-display region disposed adjacent to the display region, wherein a pad region is disposed in the non-display region, the display panel including:
pixels disposed in the display region; and
a signal pad connected to the pixels through a signal line and disposed in the pad region, wherein
the signal pad includes:
a first conductive pattern connected to a portion of the signal line;
a second conductive pattern disposed on the first conductive pattern;
a third conductive pattern disposed on the second conductive pattern; and
an insulating pattern disposed between the second conductive pattern and the third conductive pattern,
an opening is disposed in at least one of the first conductive pattern and the second conductive pattern, and
the opening overlaps the insulating pattern.

2. The display module of claim 1, wherein
the insulating pattern comprises a central portion overlapping the opening,
the insulating pattern further comprises a side portion that does not overlap the opening, and
the central portion protrudes further from at least one of the first conductive pattern and the second conductive pattern towards the third conductive pattern than the side portion.

3. The display module of claim 2, wherein the side portion of the insulating pattern overlaps each of the first conductive pattern and the second conductive pattern.

4. The display module of claim 1, wherein the insulating pattern has a greater area than the opening in a plan view.

5. The display module of claim 1, wherein
the opening is disposed in the second conductive pattern,
the insulating pattern fills the opening, and
the insulating pattern is disposed directly on the first conductive pattern.

6. The display module of claim 1, wherein
the opening includes a first opening and a second opening,
the first opening is disposed in the first conductive pattern,
the first opening overlaps the insulating pattern,
the second opening is disposed in the second conductive pattern, and
the insulating pattern overlaps the second opening and is disposed in the second opening.

7. The display module of claim 1, wherein
the signal pad further comprises a reinforcing pattern having a greater hardness than the insulating pattern, and
the reinforcing pattern overlaps the opening in a plan view.

8. The display module of claim 7, wherein the reinforcing pattern comprises metal.

9. The display module of claim 7, wherein the reinforcing pattern comprises molybdenum (Mo).

10. The display module of claim 7, wherein
the opening is disposed in the second conductive pattern,
the reinforcing pattern is disposed directly under the first conductive pattern, and
the insulating pattern is disposed directly on the first conductive pattern.

11. The display module of claim 7, wherein
the opening is disposed in the second conductive pattern,
the reinforcing pattern is disposed in the opening, and
the insulating pattern is disposed directly on the reinforcing pattern.

12. The display module of claim 7, wherein
the opening includes a first opening and a second opening,
the first opening is disposed in the first conductive pattern,
the second opening is disposed in the second conductive pattern,
the insulating pattern overlaps the first opening and the second opening,
the reinforcing pattern is disposed in the first opening, and
the insulating pattern is disposed directly on the reinforcing pattern.

13. The display module of claim 7, wherein
the opening is disposed in the first conductive pattern,
the reinforcing pattern is disposed in the opening, and
the insulating pattern is disposed directly on the second conductive pattern.

14. The display module of claim 1, wherein
the display panel comprises a base layer, a circuit element layer disposed on the base layer, and a light emitting element layer disposed on the circuit element layer in the display region, the light emitting element layer including a light emitting element,
the circuit element layer includes:
a transistor that includes a semiconductor pattern including a channel, a source, and a drain, and a gate electrode, the semiconductor pattern and the gate electrode are disposed at different layers from each other;
a first connection electrode connected to the transistor; and
a second connection electrode connected to the light emitting element,
the first conductive pattern and the first connection electrode are formed from a same layer, and
the second conductive pattern and the second connection electrode are formed from a same layer.

15. The display module of claim 14, wherein
the circuit element layer further comprises an upper electrode that overlaps the gate electrode in a plan view,
a capacitor includes the upper electrode and the gate electrode,
the signal pad further comprises a reinforcing pattern having a greater hardness than the insulating pattern,
the reinforcing pattern overlaps the opening in a plan view, and
the reinforcing pattern and the upper electrode are formed from a same layer.

16. The display module of claim 1, further comprising:
an input sensing unit disposed on the display panel, wherein
the input sensing unit includes:
a first sensing conductive layer;
a first sensing insulating layer disposed on the first sensing conductive layer; and
a second sensing conductive layer disposed on the first sensing insulating layer, and
the third conductive pattern of the signal pad and at least one of the first sensing conductive layer and the second sensing conductive layer of the input sensing unit are formed from a same layer.

17. The display module of claim 1, wherein the insulating pattern comprises a polymer.

18. The display module of claim 1, wherein
the first conductive pattern, the second conductive pattern, and the third conductive pattern each comprise a first layer, a second layer, and a third layer, and
the first layer and the third layer have a smaller electrical conductivity than the second layer.

19. The display module of claim 18, wherein
the first layer and the third layer each comprise titanium (Ti), and
the second layer comprises aluminum (Al).

20. An electronic device comprising:
a display module including:
a display panel including a display region, and a non-display region disposed adjacent to the display region, wherein a pad region is disposed in the non-display region, the display panel including:
pixels disposed in the display region; and
a signal pad connected to the pixels through a signal line and disposed in the pad region; and
an input sensing unit disposed on the display panel;
an electronic component including a bump electrode disposed in the pad region; and
an adhesive layer bonding the display panel and the electronic component, wherein
the input sensing unit includes:
a first sensing conductive layer disposed on the display panel,
a first sensing insulating layer disposed on the first sensing conductive layer, and
a second sensing conductive layer disposed on the first sensing insulating layer,
the signal pad includes:
a first conductive pattern connected to a portion of the signal line;
a second conductive pattern disposed on the first conductive pattern;
a third conductive pattern disposed on the second conductive pattern; and
an insulating pattern disposed between the second conductive pattern and the third conductive pattern,
an opening is disposed in at least one of the first conductive pattern and the second conductive pattern,
the insulating pattern includes a central portion overlapping the opening and a side portion that does not overlap the opening, and
the central portion protrudes further from at least one of the first conductive pattern and the second conductive pattern towards the third conductive pattern than the side portion.
